(19) United States
(12) Patent Application Publication
(10) Pub. No.: US 2015/0255547 A1
(43) Pub. Date: Sep. 10, 2015

(54) III-Nitride High Electron Mobility Transistor Structures and Methods for Fabrication of Same

(71) Applicant: Agency for Science, Technology and Research, Singapore (SG)

(72) Inventors: Li Yuan, Singapore (SG); Patrick Guo Qiang Lo, Singapore (SG); Haifeng Sun, Singapore (SG); Kean Boon Lee, Singapore (SG); Weizhu Wang, Singapore (SG); Susai Lawrence Selvaraj, Singapore (SG)

(73) Assignee: Agency for Science, Technology and Research, Singapore (SG)

(21) Appl. No.: 14/389,043

(22) PCT Filed: Mar. 28, 2013
(86) PCT No.: PCT/SG2013/000125

§ 371 Date: Sep. 29, 2014

(30) Foreign Application Priority Data
Mar. 29, 2012 (SG) 201202296-8
Mar. 29, 2012 (SG) 201202297-6
Mar. 29, 2012 (SG) 201202316-4
Dec. 20, 2012 (SG) 201209463-7
Dec. 26, 2012 (SG) 201209553-5

(51) Int. Cl. H01L 29/205; H01L 29/201; H01L 29/872; H01L 29/06; H01L 29/40; H01L 29/20; H01L 29/778

(52) U.S. Cl. CPC H01L 29/205; H01L 29/2003; H01L 29/201; H01L 29/7787; H01L 29/0634; H01L 29/402; H01L 29/7788; H01L 29/872

(57) ABSTRACT

Structures for III-nitride GaN high electron mobility transistors (HEMT), method for fabricating for GaN devices and integrated chip-level power systems using the GaN devices are provided. The GaN HEMT structure includes a substrate, an AlGaN/GaN heterostructure grown on the substrate, and a normally-off GaN device fabricated on the AlGaN/GaN heterostructure. The AlGaN/GaN heterostructure includes a GaN buffer layer and an AlGaN barrier layer. The integrated chip-level power system includes a substrate, an AlGaN/GaN heterostructure layer grown on the substrate and a plurality of GaN devices. The AlGaN/GaN heterostructure layer includes a GaN buffer layer and an AlGaN barrier layer and is formed into mesa areas and valley areas. Each of the plurality of GaN devices are fabricated on a separate one of the mesa areas.

### PRIORITY CLAIMS

The present application claims priority to the following Singapore patent applications: 201202296-8 (filed 29 Mar. 2012); 201202297-6 (filed 29 Mar. 2012); 201202316-4 (filed 29 Mar. 2012); 201209463-7 (filed 20 Dec. 2012); and 201209553-5 (filed 26 Dec. 2012).

### TECHNICAL FIELD

The present invention generally relates to transistor structures and methods of fabrication of such structures, and more particularly relates to III-nitride high electron mobility transistor (HEMT) structures and methods of fabricating HEMTs.

### BACKGROUND

Wide-band gap semiconductors using materials such as Gallium nitride (GaN) and aluminum gallium nitride (AlGaN) have attracted a lot of attention recently owing to the material advantages for high power, high frequency, high efficiency and high temperature applications. Especially, in III-nitride materials, high quality hetero-junctions can be created. Such hetero-junctions are directly related to a high carrier mobility channel leading to semiconductor devices with superior performance. For power electronic applications, both high breakdown voltage and low on-resistance are important for increasing output power density, operation speed and reduced power loss. However, there is a trade-off between breakdown voltage and on-resistance of a given semiconductor material. Due to its beneficial properties, such as wide bandgap, high electron mobility, and good thermal conductivity, GaN provides a useful material for high output power, high-frequency, high-efficiency, and high-temperature operation.

While tremendous progress has been made in GaN HEMT technology, many challenges still remain. Most importantly, there is a lack of reliable threshold voltage modulation techniques. Conventional AlGaN/GaN HEMT have channels featuring high carrier density even without any intentional doping. In order to turn off such devices, a negative gate bias must be applied. As a result, conventional AlGaN/GaN HEMTs are normally ON devices and feature negative threshold voltages. Yet, a drawback of normally ON HEMT structures is that in order to turn off the channel, a negative gate voltage is needed.

Thus, for simpler circuit configuration and failsafe operation, normally OFF operation is strongly preferred as it is compatible with current Si-based Power MOSFETs and IGBTs. Further, due to the high carrier density of 2 DEG channel in conventional GaN HEMT in the OFF state, the depletion region is narrow and very close to the gate edge. Thus, the peak of the electrical field is high and leakage currents from the gate or a buffer can easily trigger an avalanche breakdown, resulting in a low breakdown voltage. Also, due to the strong polarization effect and unique crystal property of the wurtzite III-nitride hetero-structure, there are a number of donor-like traps on top of the III-nitride surface arising from the Ga adatom dangling bonds. During the dynamic switching of III-nitride based transistors, these donor-like traps can be charged and discharged, affecting the channel conductance between gate and source/drain and causing a current collapse effect which threatens the stable operation of the power transistors and also limits the output current density.

Lateral confined growth (LCG) of GaN films on patterned Si substrates can be used to decrease defect densities and release the tensile stress of HEMT structures. However, due to the difference in growth rates for mesa areas and trench areas, the substrate surface cannot be fully coalesced, and accordingly has gaps formed between mesa areas. As the area ratio of edge-to-mesa plays a very important role in the effectiveness of LCG techniques, the mesa area cannot be very large. However, the area of a typical multi-finger power device for hundreds of watts output power can reach several mm² or more, dimensions too large for LCG. Thus, application of LCG growth methods to GaN power electronics is problematic due to the large dimensions.

Thus, what is needed is GaN HEMT structures and fabrication techniques which can overcome drawbacks of current GaN HEMT structures and fabrication techniques. Furthermore, other desirable features and characteristics will become apparent from the subsequent detailed description and the appended claims, taken in conjunction with the accompanying drawings and this background of the disclosure.

### SUMMARY

According to the Detailed Description, a GaN high electron mobility transistor (HEMT) structure is provided. The GaN HEMT structure includes a substrate, an AlGaN/GaN heterostructure grown on the substrate, and a normally-off GaN device fabricated on the AlGaN/GaN heterostructure. The AlGaN/GaN heterostructure includes a GaN buffer layer and an AlGaN barrier layer.

Also, a native-off III-nitride lateral diode structure is provided. The lateral diode structure includes a substrate, an AlGaN/GaN heterostructure grown on the substrate, and a normally-off GaN device fabricated on the AlGaN/GaN heterostructure.

Further, an integrated chip-level power system is provided. The integrated chip-level power system includes a substrate, an AlGaN/GaN heterostructure layer grown on the substrate and a plurality of GaN devices. The AlGaN/GaN heterostructure layer includes a GaN buffer layer and an AlGaN barrier layer and is formed into mesa areas and valley areas. Each of the plurality of GaN devices are fabricated on a separate one of the mesa areas.

In addition, a method is provided for fabrication of a GaN structure. The method includes providing a substrate, growing a AlGaN/GaN heterostructure having a GaN buffer layer and a AlGaN barrier layer on the substrate, and fabricating a normally-off GaN device on the AlGaN/GaN heterostructure

### BRIEF DESCRIPTION OF THE DRAWINGS

The accompanying figures, where like reference numerals refer to identical or functionally similar elements throughout the separate views and which together with the detailed description below are incorporated in and form part of the specification, serve to illustrate various embodiments and to explain various principles and advantages in accordance with a present invention.

FIG. 1, comprising FIGS. 1A, 1B and 1C, illustrates conventional III-nitride high electron mobility transistor (HEMT) structures and their properties, wherein FIG. 1A is a graph of trade-off characteristics between specific on-resistance (Rₒₙ) and off-state breakdown voltage (BV) of Si, SiC and GaN devices; FIG. 1B is a schematic view of a conventional normally-on AlGaN/GaN HEMT in both an ON state and an OFF state; and FIG. 1C is a schematic device structure of a p-n super junction Si laterally diffused metal oxide semiconductor (LDMOS) device.

FIG. 2 illustrates a schematic of a structure of a normally-off GaN HEMT in accordance with a first embodiment.

FIG. 3, comprising FIGS. 3A, 3B and 3C, illustrates schematic cross section views of the normally-off GaN HEMT device depicted in FIG. 2 during operation in accordance with the first embodiment, wherein FIG. 3A depicts the normally-off GaN HEMT in an OFF state, FIG. 3B depicts the normally-off GaN HEMT device as electrons pass through a region “A” and are collected by drain electrodes, and FIG. 3C depicts the normally-off GaN HEMT in an ON state.

FIG. 4, comprising FIGS. 4A to 4E, illustrates an exemplary fabrication process for the normally-off GaN HEMT depicted in FIG. 2 wherein FIGS. 4A to 4F depict various steps in the fabrication process in accordance with the first embodiment.

FIG. 5, comprising FIGS. 5A and 5B, illustrates graphs of device characteristics of normally-off vertical GaN HEMTs in accordance with the first embodiment, wherein FIG. 5A is a graph depicting gate-source voltage versus drain current for the normally-off GaN HEMT depicted in FIG. 2 and FIG. 5B is a graph depicting gate-source voltage versus drain current for variously doped variants of the normally-off GaN HEMT depicted in FIG. 2.

FIG. 6, comprising FIGS. 6A, 6B and 6C, illustrates graphs of device characteristics of normally-off vertical GaN HEMTs in accordance with the first embodiment, wherein FIG. 6A is a graph depicting gate-source voltage versus drain current for variously doped variants of the normally-off GaN HEMT depicted in FIG. 2, FIG. 6B is a graph depicting gate-source voltage versus drain current for variously thick variants of the normally-off GaN HEMT depicted in FIG. 2, and FIG. 6C is a graph depicting gate-source voltage versus drain current for variously regrown thickness variants of the normally-off GaN HEMT depicted in FIG. 2.

FIG. 7 illustrates a schematic cross section view of a self-aligned source ohmic contact and drain field plate (SSDF) III-nitride HEMT and a corresponding band diagram in accordance with a second embodiment.

FIG. 8, comprising FIGS. 8A and 8B, illustrate graphs of device characteristics of the SSDF III-nitride HEMT in accordance with the second embodiment, wherein FIG. 8A is a graph of barrier thickness versus two-dimensional electron gas (2 DEG) conduction channel thickness of the SSDF III-nitride HEMT of FIG. 7 and FIG. 8B is a graph of a conduction band energy profile of the SSDF III-nitride HEMT of FIG. 7.

FIG. 9, comprising FIGS. 9A, 9B and 9C, illustrates schematic cross section views of a SSDF HEMT device in accordance with the second embodiment and a conventional HEMT device, wherein FIG. 9A is a schematic cross section of the SSDF HEMT device, FIG. 9B is a schematic cross section of a conventional HEMT, and FIG. 9C is a schematic cross section of a SSDF HEMT device zooming in on a source and gate region of the SSDF HEMT device.

FIG. 10 illustrates a graph in linear scale of gate-source voltage versus drain-source current of HEMT devices including a SSDF HEMT device in accordance with the second embodiment.

FIG. 11 illustrates a graph in linear scale of gate-source voltage versus gate transconductance of HEMT devices including a SSDF HEMT device in accordance with the second embodiment.

FIG. 12 illustrates a graph in log scale of gate-source voltage versus drain-source current of a conventional HEMT device and a SSDF HEMT device in accordance with the second embodiment.

FIG. 13 illustrates a graph of gate-source voltage versus drain-source current of a SSDF HEMT device in accordance with the second embodiment with a five nanometer (nm) AlGaN barrier.

FIG. 14 illustrates a graph of gate-source voltage versus drain-source current of SSDF HEMT devices in accordance with the second embodiment with various drain field plate coverage.

FIG. 15, comprising FIGS. 15A and 15B, illustrates graphs of gate-source voltage versus drain-source current of SSDF HEMT devices in accordance with the second embodiment with various gate dielectric thicknesses, wherein FIG. 15A is a graph in linear scale and FIG. 15B is a graph in log scale.

FIG. 16, comprising FIGS. 16A to 16E, illustrates views and graphs of a AlGaN/GaN HEMT devices in accordance with a third embodiment, wherein FIG. 16A is a schematic cross section and conduction band profile of gate electron tunneling and surface trapping of the AlGaN/GaN HEMT devices, FIG. 16B is a graph of a transient simulation of operation of the AlGaN/GaN HEMT devices; FIG. 16C is a graph of gate-source voltage versus drain-source current for various gate drain lengths of the AlGaN/GaN HEMT device in accordance with the third embodiment, FIG. 16D is a graph of gate-source voltage versus current for various surface traps of the AlGaN/GaN HEMT device in accordance with the third embodiment, and FIG. 16E is a graph of time versus drain-source current for the various surface traps of the AlGaN/GaN HEMT device in accordance with the third embodiment.

FIG. 17 illustrates a schematic cross section view of a surface state energy level modulated (SSEM) III-nitride. HEMT device in accordance with the third embodiment.

FIG. 18, comprising FIGS. 18A and 18B, illustrates schematic cross sections of the SSEM III-nitride HEMT device in accordance with the third embodiment, wherein FIG. 18A is a schematic cross section of the SSEM III-nitride HEMT device and FIG. 18B is a zoom-in schematic cross section view of a gate region of the SSEM III-nitride HEMT device.

FIG. 19 illustrates a graph in log scale of gate-source voltage versus drain-source current of the SSEM III-nitride HEMT device in accordance with the third embodiment.

FIG. 20 illustrates a graph of conduction band profiles between gate and drain for a conventional HEMT and for SSEM III-nitride HEMT devices in accordance with the third embodiment.

FIG. 21 illustrates a graph of conduction band profiles under a gate of a SSEM III-nitride HEMT device in accordance with the third embodiment having various dopant levels of a negative charge doped gate dielectric layer.

FIG. 22 illustrates a graph in log scale of transient behaviors for a conventional HEMT and for SSEM III-nitride HEMT devices in accordance with the third embodiment.

FIG. 23 illustrates a graph in linear scale of transient behaviors for a conventional HEMT and for SSEM III-nitride HEMT devices in accordance with the third embodiment.

FIG. 24 illustrates a graph of gate-source voltage versus drain-source current for SSEM III-nitride HEMT devices in accordance with the third embodiment having an AlGaN cap layer of various high Al mole-fractions.

FIG. 25 illustrates a graph of gate-source voltage versus drain-source current for SSEM III-nitride HEMT devices in accordance with the third embodiment having various surface negative charge doping levels.

FIG. 26 illustrates a graph of gate-source voltage versus drain-source current for SSEM III-nitride HEMT devices in accordance with the third embodiment.

FIG. 27 illustrates a graph of OFF state gate-source voltage versus drain-source current for SSEM III-nitride HEMT devices in accordance with the third embodiment formed using surface negative charge doping.

FIG. 28, comprising FIGS. 28A to 28E, illustrates schematic cross section views of a lateral negative charge assisted super junction (NSJ) and interval-finger gate field plate III-nitride HEMT in accordance with a fourth embodiment, wherein FIG. 28A is a three-dimensional perspective view of a normally ON NSJ III-nitride HEMT, FIG. 28B is a three-dimensional perspective view of a normally OFF NSJ III-nitride HEMT, FIG. 28C is a two-dimensional x-y cross section side view of a normally ON NSJ III-nitride HEMT, FIG. 28D is a two-dimensional z-y cross section side view of a normally ON NSJ III-nitride HEMT, and FIG. 28E is a two-dimensional x-z cross section top view of a normally ON NSJ III-nitride HEMT.

FIG. 29, comprising FIGS. 29A and 29B, illustrates schematic cross section views of HEMTs, wherein FIG. 29A is a schematic cross section view of a conventional HEMT and FIG. 29B is a schematic cross section view of a NSJ III-nitride HEMT in accordance with the fourth embodiment.

FIG. 30 illustrates a three-dimensional perspective view of a NSJ III-nitride HEMT in accordance with the fourth embodiment.

FIG. 31 illustrates a graph of OFF state gate-source voltage versus drain-source current for a conventional HEMT device and a NSJ III-nitride HEMT device in accordance with the fourth embodiment.

FIG. 32 illustrates a graph in log scale of gate-source voltage versus drain-source current for a conventional HEMT device and a NSJ III-nitride HEMT device in accordance with the fourth embodiment.

FIG. 33 illustrates a graph in linear scale of gate-source voltage versus drain-source current for a conventional HEMT device, a negative-doped HEMT device without a super junction, and a NSJ III-nitride HEMT device in accordance with the fourth embodiment.

FIG. 34 illustrates a three-dimensional perspective view of a NSJ III-nitride HEMT device in accordance with the fourth embodiment showing a conduction band distribution of the NSJ III-nitride HEMT device in the OFF state.

FIG. 35 illustrates a graph of F doping concentrations of ion implantation on a SiN/AlGaN/GaN epitaxial structure for a NSJ III-nitride HEMT device in accordance with the fourth embodiment.

FIG. 36 illustrates a schematic cross section view and a corresponding conduction band diagram of a native-off III-nitride power electronics platform including a normally-off SSDF HEMT and a lateral diode in accordance with a fifth embodiment.

FIG. 37, comprising FIGS. 37A to 37F, illustrates an exemplary fabrication process for the native-off III-nitride lateral diode in accordance with the fifth embodiment, wherein FIGS. 37A to 37F depict various steps in the fabrication process.

FIG. 38, comprising FIGS. 38A, 38B and 38C, illustrates schematic cross section views, wherein FIG. 38A is a schematic cross section view of the native-off III-nitride lateral diode in accordance with the fifth embodiment, FIG. 38B is a schematic cross section view of a GaN Schottky barrier diode (SBD), and FIG. 38C is a schematic cross section view of a GaN p-i-n diode.

FIG. 39 illustrates a schematic epitaxial structure cross section view of a native-off III-nitride lateral diode device in accordance with the fifth embodiment.

FIG. 40 illustrates a linear scale graph of current-voltage characteristics of a SBD device, a p-i-n device and a native-off III-nitride lateral diode in accordance with the fifth embodiment for voltages ranging from minus five volts to five volts.

FIG. 41 illustrates a linear scale graph of current-voltage characteristics of a SBD device, a p-i-n device and a native-off III-nitride lateral diode in accordance with the fifth embodiment for voltages ranging from minus twenty volts to twenty volts.

FIG. 42 illustrates a log scale graph of current-voltage characteristics of a native-off III-nitride lateral diode in accordance with the fifth embodiment.

FIG. 43, comprising FIGS. 43A and 43B, illustrates graphs of current-voltage characteristics of a native-off III-nitride lateral diode in accordance with the fifth embodiment having different anode field plate coverages, wherein FIG. 43A is a linear scale graph and FIG. 43B is a log scale graph.

FIG. 44, comprising FIGS. 44A, 44B and 43C, illustrates graphs of current-voltage characteristics of a native-off III-nitride lateral diode in accordance with the fifth embodiment having different Shottky dielectric thicknesses, wherein FIG. 44A is a linear scale graph having voltages from minus three volts to three volts, FIG. 44B is a linear scale graph having voltages from minus ten volts to twenty volts, and FIG. 44C is a log scale graph having voltages from minus ten volts to twenty volts.

FIG. 45, comprising FIGS. 45A and 45B, illustrates perspective schematic views of patterned silicon (Si) substrates, wherein FIG. 45A is a conventional patterned Si substrate and FIG. 45B is a patterned schematic structure of a power integration system in accordance with a sixth embodiment after fabrication (using 4×4 units as an example).

FIG. 46 illustrates a schematic cross section view of a grown hetero-structure of the system in accordance with the sixth embodiment.

FIG. 47, comprising FIGS. 47A and 47B, illustrates schematic cross section views of grown devices after fabrication of the power integration system in accordance with the sixth embodiment, wherein FIG. 47A has the structures connected in parallel and FIG. 47B has the structures connected in series.

FIG. 48 illustrates a circuit diagram of structures coupled into a power integration system in accordance with the sixth embodiment.

FIG. 49 illustrates a schematic cross section view of an epitaxial structure of a single AlGaN/GaN HEMT transistor of the power integration system in accordance with the sixth embodiment.

FIG. 50 illustrates a log scale graph of gate-source voltage versus drain-source current transfer characteristics of a single transistor in the system in accordance with the sixth embodiment.

FIG. 51 illustrates a linear scale graph of gate-source voltage versus drain-source current transfer characteristics of a single transistor and a double transistor pair connected in parallel in the system in accordance with the sixth embodiment.

And FIG. 52 illustrates a linear scale graph of gate-source voltage versus drain-source current transfer characteristics of a single transistor and a double transistor pair connected in series in the system in accordance with the sixth embodiment.

Skilled artisans will appreciate that elements in the figures are illustrated for simplicity and clarity and have not necessarily been depicted to scale. For example, the dimensions of some of the elements in the block diagrams may be exaggerated in respect to other elements to help to improve understanding of the present embodiments.

### DETAILED DESCRIPTION

The following detailed description is merely exemplary in nature and is not intended to limit the invention or the application and uses of the invention. Furthermore, there is no intention to be bound by any theory presented in the preceding background or the following detailed description. It is the intent of this description to present improved structures and fabrication techniques for gallium nitride high electron mobility transistors (GaN HEMTs).

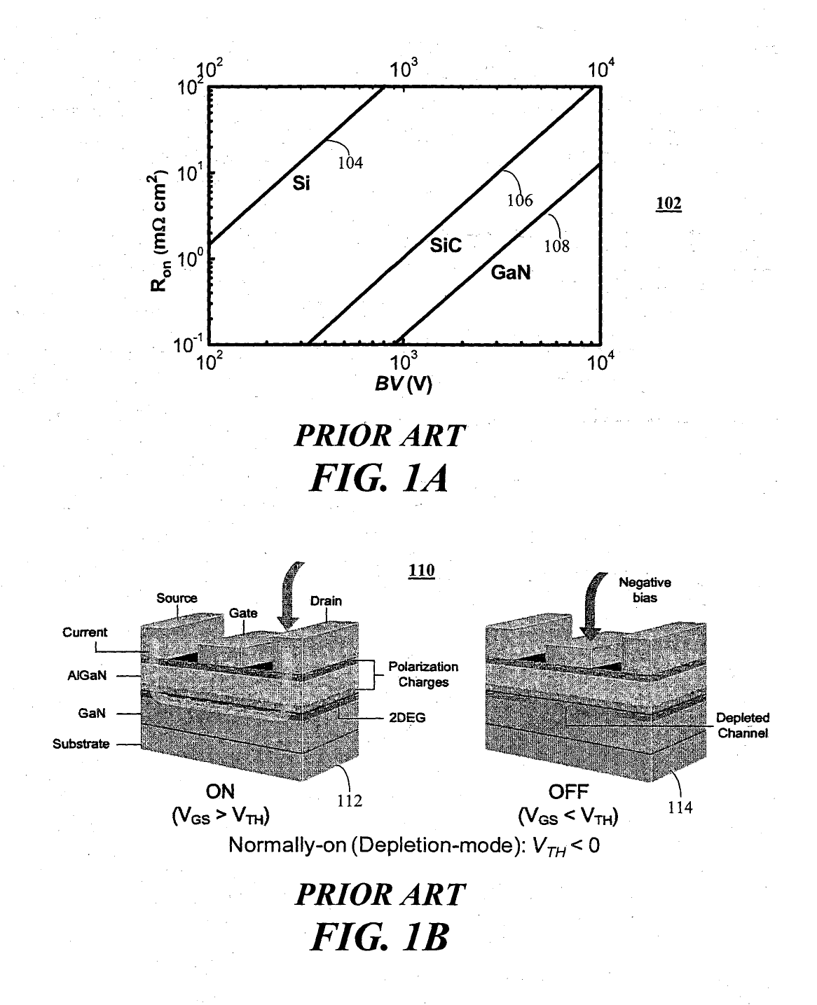

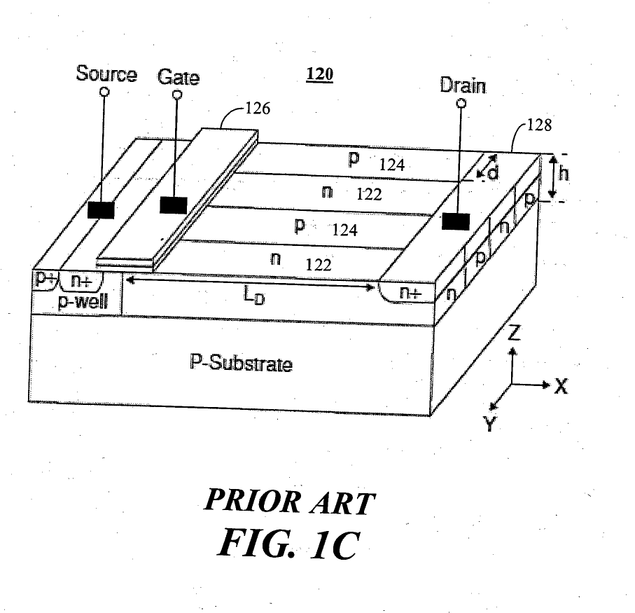

For power electronic applications, both high breakdown voltage and low on-resistance are important for increasing output power density, operation speed and reduced power loss. However, there is a trade-off between breakdown voltage and on-resistance of a given semiconductor material. Referring to FIG. 1A, a graph 102 of theoretical trade-off characteristics between specific on-resistance (Rₒₙ) and off-state breakdown voltage (BV) of Si devices 104, SiC devices 106 and GaN devices 108 is depicted. As can be seen from FIG. 1A, as the breakdown voltage increases, the on-resistance of the semiconductor devices will also increase, thereby identifying a limit on the on-state current driving capability. As can also be seen from FIG. 1A, GaN devices 108 can provide much better performance as compared to Si devices 104 or. SiC devices 106. For example, at a thousand volt breakdown voltage, the on-resistance of GaN device 108 is three orders lower than the breakdown voltage of Si 104. Thus, due to its beneficial properties, such as wide bandgap, high electron mobility, and good thermal conductivity, GaN provides a useful material for high output power, high-frequency, high-efficiency, and high-temperature operation.

Also, as compared to its nearest competitor SiC, all properties of GaN except for thermal conductivity measure comparably or even better. More importantly, for semiconductors using GaN materials as opposed to semiconductors using SiC materials, high quality AlGaN/GaN heterostructures can be fabricated. The quality of these heterostructures is directly related to the high electron mobility of two-dimensional electron gas (2 DEG) conduction channels. Therefore, GaN devices, especially AlGaN/GaN hetero junction based high electron mobility transistors (HEMTs) can deliver superior device performance for high power, high efficiency and high switching frequency applications. In addition, the operating temperature of such GaN HEMTs (>300° C.) is larger than conventional Si based power devices, thereby requiring less complex cooling systems.

Conventional AlGaN/GaN HEMTs are normally-on devices and feature negative threshold voltages, as shown in FIG. 1B. FIG. 1B depicts a schematic view 110 of conventional normally-on AlGaN/GaN HEMTs in both an ON state 112 and an OFF state 114. The reason most conventional GaN HEMTs are normally ON is in order to take advantage of the inherent high electron density induced, by strong, spontaneous, piezoelectric polarization. Yet, a drawback of normally ON HEMT structures is that in order to turn off the channel, a negative gate voltage is needed.

Several AlGaN/GaN HMET structures have been developed to achieve normally OFF operation using, for example, gate recesses, fluorine treatment, p-type cap layers, nano-rods and MOSHEMT. However, all of these structures reduce the 2 DEG density under the gate electrodes to realize normally OFF operation. For example, for fluorine treatment or gate recess structures, unique processes such as fluorine plasma ion implantation and ICP/RIE dry recess etching are needed, usually inducing uniformity and reliability problems. In addition, p-type doping by, for example, Mg in AlGaN/GaN has difficulty obtaining high density low defect activation. In addition, channel resistivity of MOSHEMT is large since the high electron mobility two dimensional electron gas (2 DEG) channel under the gate will be fully removed during fabrication.

As opposed to Si and GaAs whose native substrates are available relatively inexpensively, GaN substrates are expensive due to the difficulties associated with the formation of high-quality crystals of GaN. Recently, only foreign substrates such as sapphire, SiC, and Si have been commonly used for GaN epitaxial growth. SiC substrates are costly and sapphire substrates are extensively used in LED applications. Therefore, epitaxially growing GaN crystals on Si substrates is preferred due to the lower cost and higher availability of large size Si substrates, especially for use in cost-driven power applications. However, the metal organic chemical vapor deposition (MOCVD) often utilized for the epitaxial growth process of GaN films on Si substrates has proven to be challenging due to a large mismatch of lattice constants (16.9%) and thermal expansion coefficients (54%) between GaN and Si. Therefore, the critical issues for GaN-on-Si growth are how to properly manipulate and minimize stress during epitaxial growth to avoid cracking after cooling and how to minimize dislocation density and bowing of the grown wafers.

In addition, power switches such as DC/DC buck converters, DC/DC boost converters or DC/AC inverters are conventionally made of AlGaN/GaN HEMTs and SiC diodes, GaN Schottky barrier diodes (SBD) or GaN p-i-n diodes. Yet, SiC diodes, GaN SBDs or GaN p-i-n diodes cannot be integrated on a AlGaN/GaN HEMT wafer with the same fabrication process, leading to higher cost, lower reliability and reduced density of such power switches. Therefore, HEMT compatible III-nitride diodes are highly desired for low cost, high reliability, high efficiency, high speed and compact size switch mode power converters.

Recent diode structures fabricatable on III-nitride material which can be integrated with HEMT include fluorine treated lateral rectifiers and lateral Schottky barrier diodes with recessed Schottky anodes. Yet, special processes (e.g., fluroine plasma treatment and AlGaN/GaN recess etching) are required in order to fabricate these devices, leading to process induced issues such as lattice defects, low channel mobility and non-uniform device performance.

Lateral confined growth (LCG) of GaN films on patterned Si substrates can be used to decrease defect densities. LCG is also helpful to release the tensile stress of HEMT structures. Threading dislocations bend laterally and react with each other, thereby resulting in a lower dislocation density. Moreover, conventional LCG processes release tensile stress by introducing intentionally induced “cracks”, i.e., free facets at pattern edges. Compared to conventional epitaxial lateral overgrowth (ELOG) which needs to perform MOCVD growth twice, conventional LCG is simpler with only a single-step patterning process being performed before growth. Therefore, high quality HEMT heterostructures can be simply grown by conventional LCG methods.

Due to the difference in growth rates for mesa areas and trench areas, the substrate surface cannot be fully coalesced, and accordingly has gaps formed between mesa areas. As the area ratio of edge-to-mesa plays a very important role in the effectiveness of LCG techniques, the mesa area cannot be very large, typically no more than 300×300 μm². The smaller the mesa area, the better performance the LCG technique can exhibit. However, the area of a typical multi-finger power device for hundreds of watts output power can reach several mm² or more, dimensions too large for LCG.

In Si based power devices, a p-n super junction device technology is widely used to enhance the breakdown performance at a given ON resistance. A schematic device structure of a conventional p-n junction 120 in Si LDMOS is shown in FIG. 1C. This structure can be achieved by introducing alternating n columns 122 and p columns 124 with the same doping concentration in a drift region between a gate 126 and a drain 128, the doping in this region being higher than conventional LDMOS. In the OFF state, the V_{DS} will drop along the drift region. Thus, the n channel 122 will be depleted by the adjacent p region 124, providing uniform electrical field distribution and enhancing the breakdown performance. Meanwhile, when the device is turned ON, the high electrical field will be removed and the n channel will recover to let electron carriers pass through. The doping imbalance between p and n columns 124, 122 will disadvantageously cause breakdown voltage degradation because the drift region cannot be fully depleted at high V_{DS}.

In III-nitride material, electron carrier density in the 2 DEG channel is very high (i.e., ˜10²⁰ cm⁻³). Thus, in order to fabricate p-n super junction transistors on III-nitride hetero-junctions, heavily doped (i.e., ˜10²⁰ cm⁻³) p-type regions are required. However, due to the large activation energy required for p-doping (e.g., p-doping with Mg requires 0.25 eV) and the small lattice constant (i.e., the lattice constant for GaN is 3.189 Å/5.125 Å) in III-nitride material, activation of p-doping is very difficult. The highest concentration of activated p-type dopant in III-nitride is typically only ˜10¹⁸ cm⁻³. Therefore, a p-n super junction device structure is difficult to implement in III-nitride material systems.

While conventional GaN HEMT structures reduce a two-dimensional electron gas (2 DEG) conduction channel density under gate electrodes to realize a normally-off operation, GaN HEMT structures in accordance with a first embodiment control formation of a p-n junction in order to realize normally-off operation. The normally-off vertical GaN HEMTs in accordance with the first embodiment enables controllable threshold voltage with low off-state leakage as well as small subthreshold swing, allowing the threshold voltage to be easily adjusted over a wide range. These devices also provide high breakdown voltage and current densities, making them ideal for use in power electronics applications, like power switches in automotive DC-DC converters and traction inverters.

Conventional GaN-based FETs are lateral devices due to the horizontal nature of the 2-dimensional electron gas. However, an increase of breakdown voltage would result in a larger chip size due to drift length. Furthermore, dc-RF dispersion induced by surface states would degrade the device performance. Therefore, for high power applications, a vertical topology is desirable to reduce chip area as well as to diminish current collapse. Vertical GaN devices support high breakdown voltage and current densities, which are useful for power electronic applications such as power switches in automotive DC-DC converters and traction inverters.

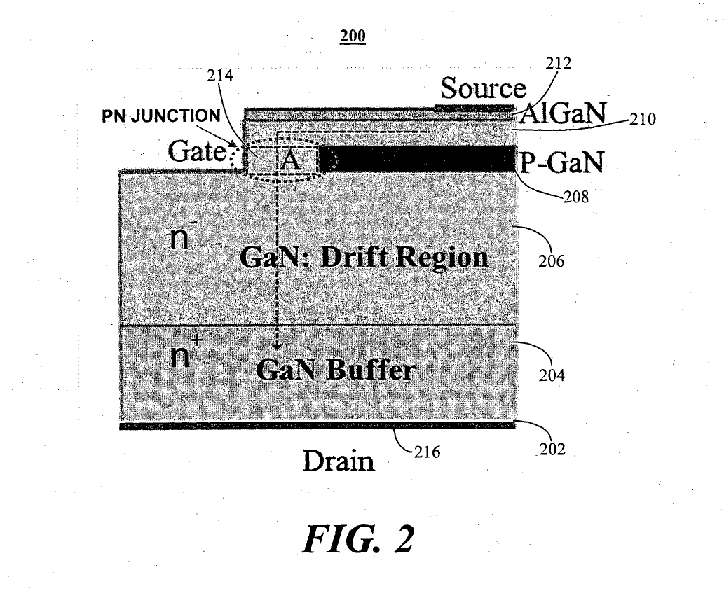

Referring to FIG. 2, a schematic structure 200 of a normally-off GaN HEMT in accordance with the first embodiment is depicted. The epi-layer can be grown on a substrate 202 of silicon (Si), sapphire, silicon carbide (SiC), or bulk gallium nitride (GaN). From the substrate 202 up, the epitaxial layer consists of a GaN buffer layer 204, a GaN drift region layer 206, a p-GaN layer 208, a GaN channel 210 and a AlGaN barrier layer 212.

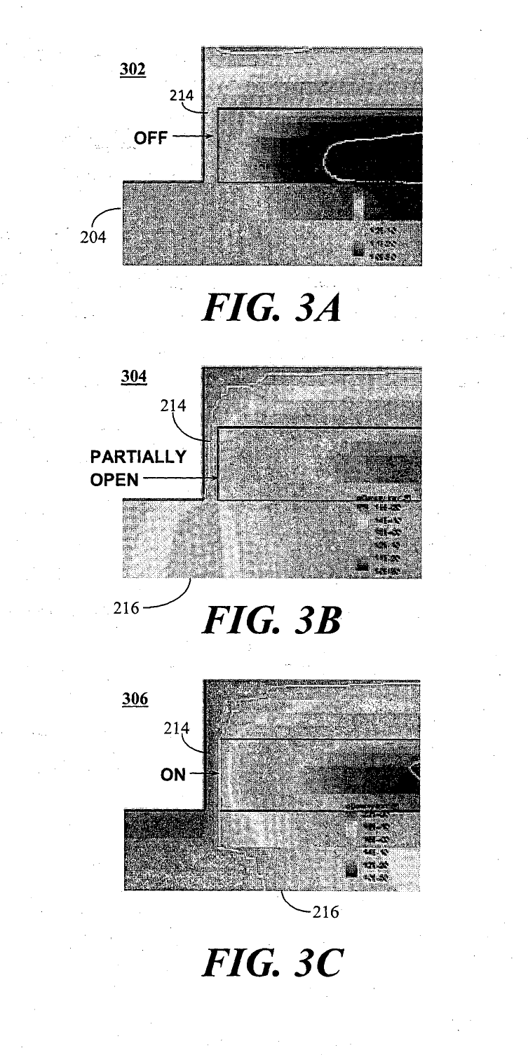

Referring to FIG. 3, comprising FIGS. 3A to 3C, schematic cross section views 302, 304, 306 depict operation principles of the normally-off vertical GaN HEMT in accordance with the first embodiment. At V_{GS}=0, gate region A 214 in FIG. 2 is depleted by choosing appropriate doping concentrations of the p-GaN layer 208 and the drift region 210. Depletion of region A 214 causes region A 214 to block the electrons in a two-dimension electron gas (2 DEG) channel. Thus, the electrons cannot reach the GaN buffer layer 204, thereby realizing a truly normally-off operation as seen in 302 (FIG. 3A). At V_{GS}>Vₜₕ the region A 214 becomes partially open so that electrons can pass through and finally are collected by drain electrode 216 as seen in 304 (FIG. 3B). At V_{GS}>>Vₜₕ, the region A 214 is completely open and all of the electrons can reach the drain electrode 216. And thus the device 200 is in the ON state as seen in 306 (FIG. 3C).

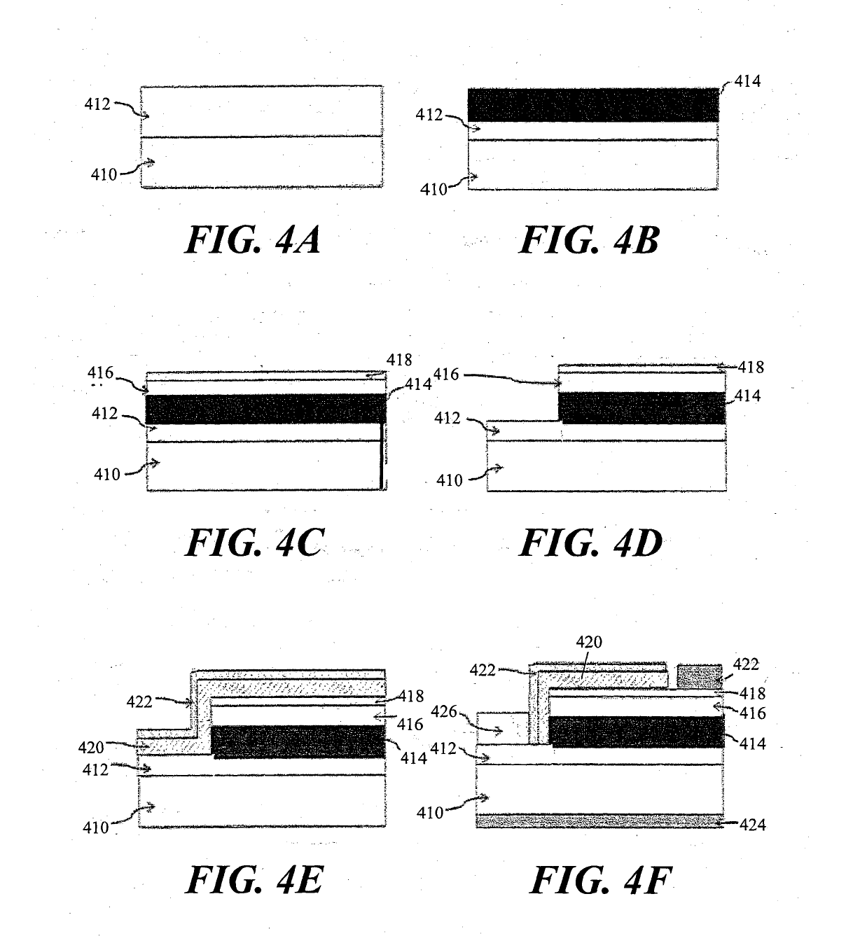

A fabrication process for the device 200 in accordance with the first embodiment is shown in FIG. 4. FIG. 4, comprising FIGS. 4A to 4E, illustrates an exemplary fabrication process for the normally-off GaN HEMT device 200. Referring to FIG. 4A, initially a two-step growth process is utilized for fabrication of the device 200. A highly doped (n+) GaN buffer layer 410 followed by a lightly doped (n−) GaN drift region layer 412 is grown by a vapor deposition process such as MOCVD. Next, referring to FIG. 4B, Magnesium (Mg) ions are implanted into the n-GaN layers using a SiN hard mask to form a p-GaN region 414. Next, as seen in FIG. 4C, a GaN channel 416 and an AlGaN barrier layer 418 are grown by MOCVD. Then, referring to FIG. 4D, high density plasma, such as inductively coupled plasma (ICP), is used for mesa etch. This step is followed by the most critical step in the process flow. This step is shown in FIG. 4E and includes a GaN regrowth to form a layer 420 followed by an in-situ SiN growth to form a layer 422. After forming the GaN layer 420 and the SiN layer 422, the contacts are formed as shown in FIG. 4F. Ti/Al based metal stacks 422, 424 are deposited, following by rapid thermal annealing, to form a source ohmic contact 422 and a drain ohmic contact 424. The drain contact 424 can be realized by through silicon via (TSV) technology if the substrates are silicon, sapphire, or SiC. Finally, as also shown in FIG. 4F, a Schottky contact 426 is formed using Ni-based metal stacks.

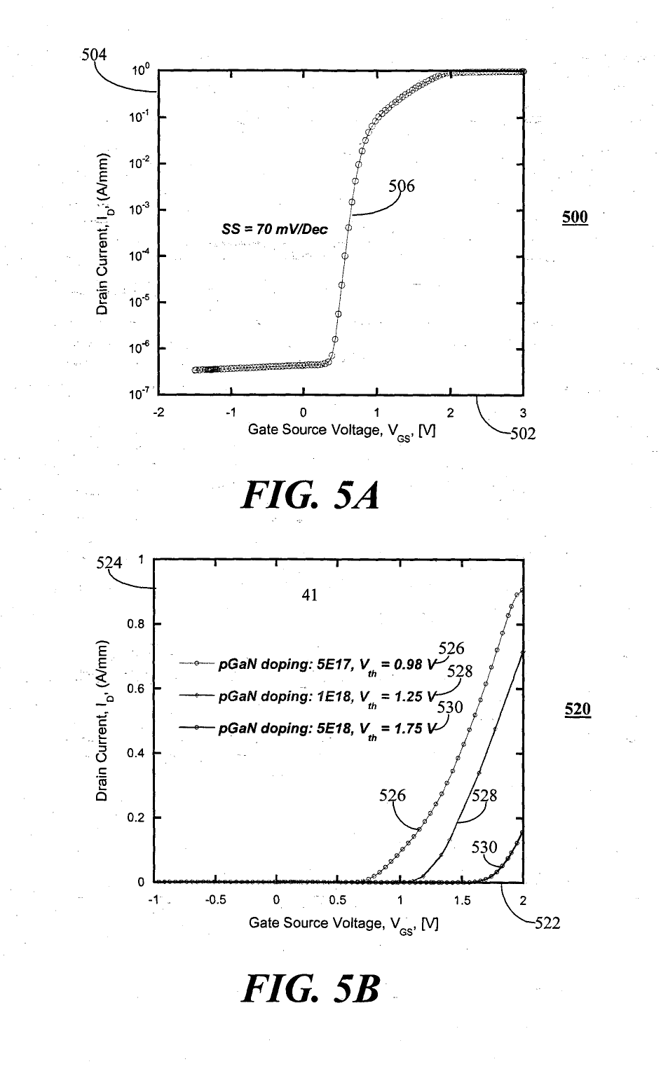

Referring next to FIG. 5, comprising FIGS. 5A and 5B, graphs 500, 520 depict device characteristics of normally-off vertical GaN HEMTs in accordance with the first embodiment. FIG. 5A depicts a graph 500 of gate-source voltage 502 versus drain current 504 for the normally-off GaN HEMT 200. Device performance of the normally-off vertical GaN HEMT 200 along a trace 506 shows that the threshold voltage of the device 200 is larger than +0.5 V, indicating true normally-off operation and low off-state leakage as well as small subthreshold swing (70 mV/Dec). Referring to FIG. 5B, the graph 520 of gate-source voltage 522 versus drain current 524 for the normally-off GaN HEMT 200 having three p-GaN region 414 doping concentrations plotted along traces 526, 528, 530 shows that the threshold voltage can be easily adjusted (e.g. from 0.98 V to 1.75 V) by choosing the doping concentration of the p-GaN region 414, advantageously enabling flexible device and circuit design.

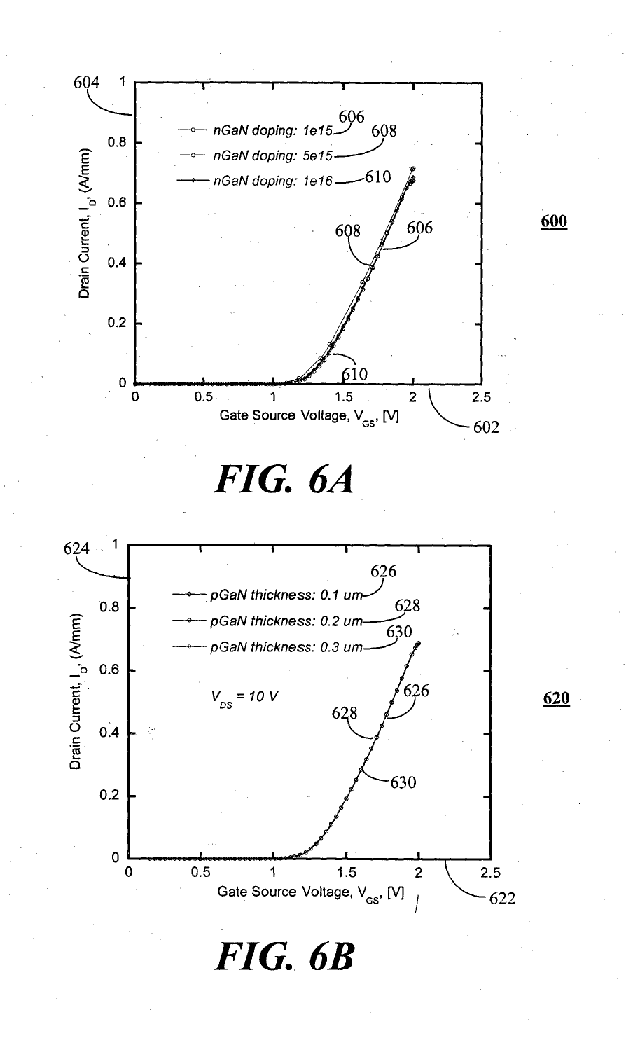

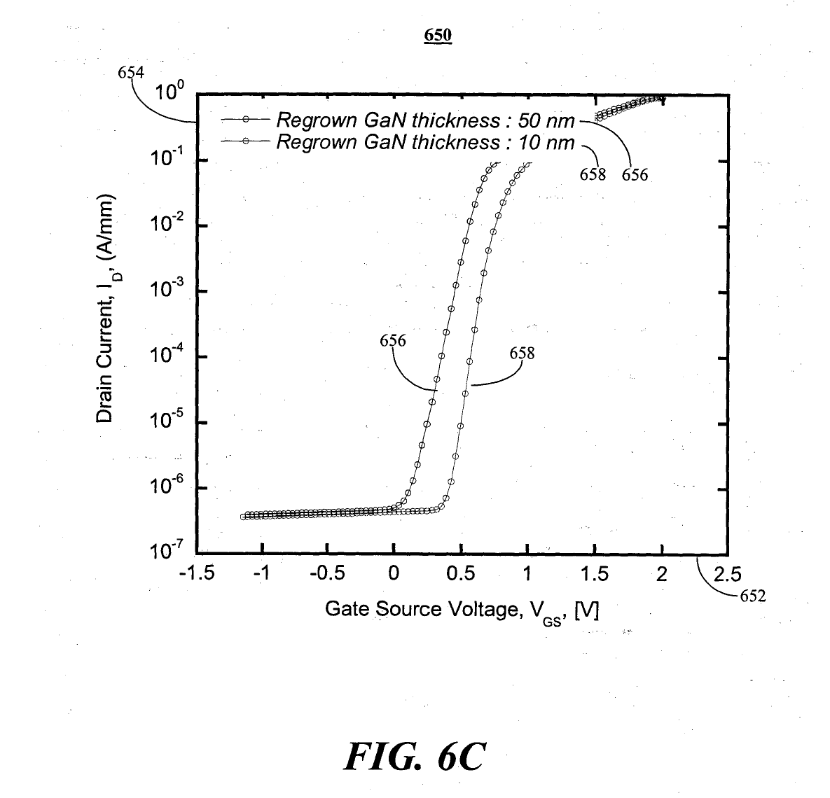

Referring next to FIG. 6, comprising FIGS. 6A, 6B and 6C, additional graphs of device characteristics of the normally-off vertical GaN HEMTs 200 in accordance with the first embodiment are depicted. Referring to FIG. 6A, a graph 600 depicting gate-source voltage 602 versus drain current 604 for the normally-off GaN HEMT 200 having variously doped n-GaN layers 410, 412 as plotted along traces 606, 608, 610 evidences that the threshold voltage does not sensitively depend on the doping concentration of the n-GaN layers 410, 412. Referring to FIG. 6B, a graph 620 depicting gate-source voltage 622 versus drain current 624 for the normally-off GaN HEMT 200 having a p-GaN layer 414 having various thicknesses as plotted on traces 416, 418, 420 also evidences that the threshold voltage does not depend on the thickness of the p-GaN layer 414. Thus, from the graphs 600, 620, those skilled in the art will realize that structure design and fabrication of the normally-off GaN HEMT 200 in accordance with the first embodiment is both flexible and robust as the doping concentrations of the n-GaN layers 410, 412 can vary and/or the thickness of the p-GaN layer 414 can vary without affecting the threshold voltage of the HEMT device 200.

Referring to FIG. 6C, a graph 650 depicting gate-source voltage 652 versus drain current 654 for various thicknesses of the regrown n-GaN layer 420 show that the threshold voltage (Vₜₕ) is not only controlled by the doping of the p-GaN layer 414 as seen in the graph 520, but is also controlled by the thickness of the regrown n-GaN layer 420. As the MOCVD technique can control the thickness of the regrown n-GaN layer 420 very precisely, fabrication of the vertical normally-off GaN HEMT device 200 advantageously allows precise definition of the threshold voltage of the HEMT device 200 in accordance with the first embodiment.

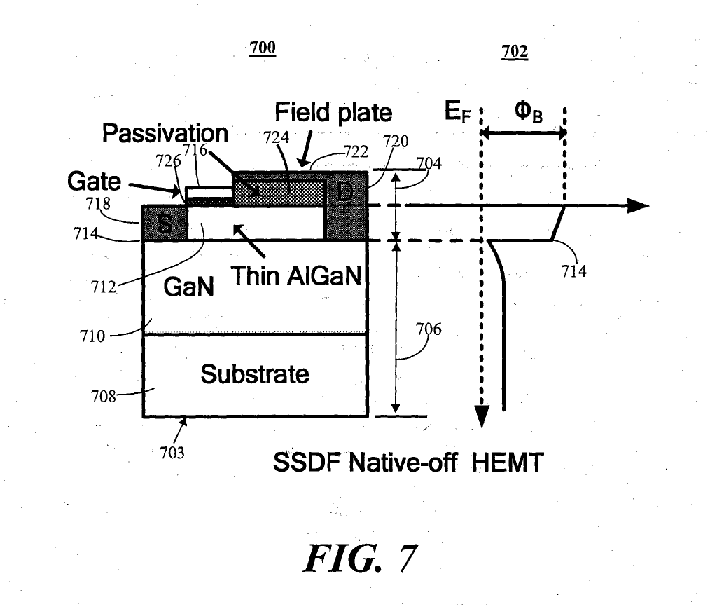

Referring to FIG. 7, a schematic cross section view 700 depicts a self-aligned source ohmic contact and drain field plate (SSDF) III-nitride HEMT and a corresponding band diagram in accordance with a second embodiment. This device structure combines surface passivation and the SSDF plate for a robust native-off AlGaN/GaN hetero junction HEMT structure. This novel structure possesses unique characteristics to realize defect free, large current driving capability (e.g., >1.5 A/mm at V_{GS}=3V), low leakage (e.g., 10 nA/mm), high trans-conductance (e.g., >900 mS/mm), small subthreshold swing (e.g., <70 mV/Dec) and high Iₒₙ/I_{off} ratio (e.g., 10⁸) enhancement mode in a III-nitride HEMT power transistor.

The schematic device cross section view 700 and a corresponding band diagram 702 for a SSDF III-nitride HEMT 703 is illustrated in FIG. 7. In order to eliminate uniformity and defect issues induced by conventional technologies, enhancement mode operation is achieved by fabricating a GaN transistor 704 on a native-off AlGaN/GaN heterostructure 706. The native-off heterostructure 706 (which means the inner 2 DEG channel is depleted even without any voltage bias) includes a substrate 708, a GaN buffer layer 710 and a AlGaN barrier layer 712 with a AlGaN/GaN interface 714 between the AlGaN barrier layer 712 and the GaN buffer layer 710. The GaN transistor 704 includes a gate 716, a source ohmic contact 718 and a drain ohmic contact 720 including a drain field plate 722 formed over a passivation layer 724.

The native-off heterostructure 706 is fabricated by growing the thin AlGaN barrier layer 712 on top of the GaN buffer 710 using MOCVD. Since no recess, doping or plasma treatment is needed during the fabrication, this native normally-off AlGaN/GaN transistor 703 can get high uniformity defect free device performance. The GaN transistor 704 is fabricated on the native-off AlGaN/GaN hetero junction 706 wherein the GaN buffer layer 710 is grown on the substrate layer 708 (e.g., a substrate such as Si, sapphire or SiC) by MOCVD with the thin (e.g., <10 nm) AlGaN barrier layer 712.

Within the native-off AlGaN/GaN hetero junction 706, the conduction band of the AlGaN/GaN interface 714 will be raised higher than Fermi level, even without any external voltage bias as shown in the conduction band diagram 702. Thus, the electron carriers in the 2 DEG channel can be completely depleted, as shown as also shown in the conduction band diagram 702. To turn on the device 703, a positive gate voltage at the gate 716 of the GaN transistor 704 is needed, thus normally-off operation can be obtained. In addition, source ohmic metal, which is self-aligned to the gate electrode 716, is deposited and annealed along the thin AlGaN barrier 712 to form a direct contact to the gate channel from the side. In this instance, self-aligned means, as shown in FIG. 7, the source ohmic metal is close to the bottom of the gate dielectric layer 726. The gate dielectric layer doesn't cover the source metal surface but covers the surface of the thin AlGaN layer 714 which directly contacts the source ohmic metal. Therefore, the channel resistance between the gate 716 and the source 718 is negligible.

Between the gate 716 and the drain contact 720, the drain field plate 722 is formed on top of the SiN passivated 724 thin AlGaN barrier 712 to enhance the on-state current driving capability and uniform electric field distribution along the 2 DEG channel. A gate dielectric layer 726 (e.g. Al₂O₃) is deposited between the gate 716 and the AlGaN barrier 712 in order to block gate leakage current, isolate the gate 716 and the self-aligned source electrode 718 and modulate the threshold voltage of the SSDF III-nitride HEMT 703.

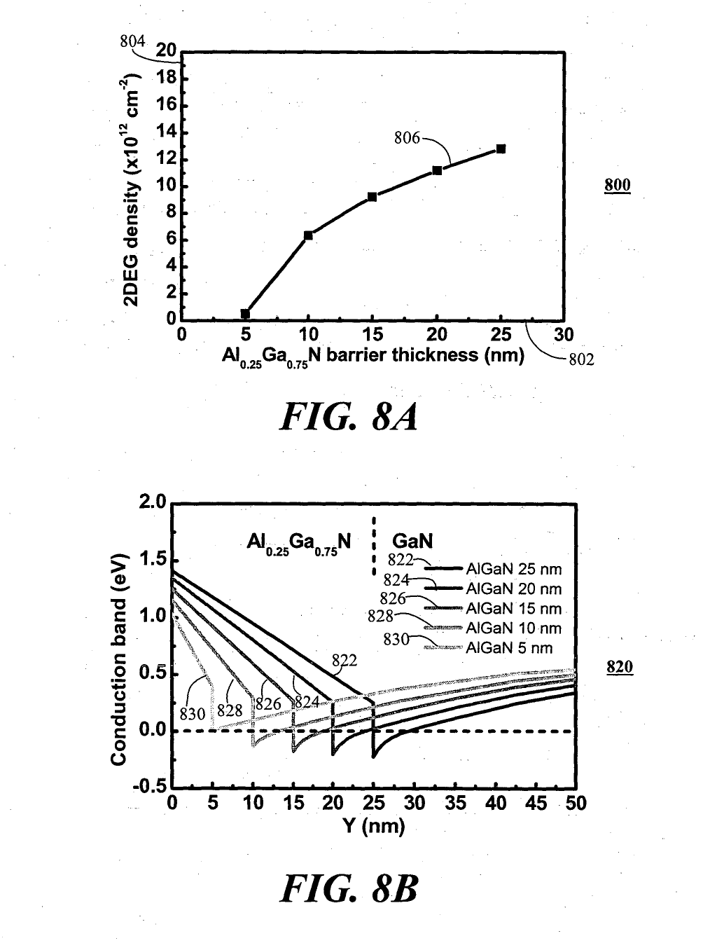

Both the SSDF III-nitride HEMT 703 and a conventional. HEMT have similar device features. Particularly, the contact length of source, gate and drain and the gate to drain distance are substantially the same in both. In a conventional HEMT, the gate to source distance is small (e.g., 1 μm) and for the SSDF III-nitride HEMT 703, the source 718 is self-aligned to the gate 716 as shown in FIG. 7. For the simulation data points generated for FIGS. 8 and 10 to 16, the GaN buffer 710 thickness is approximately 2 μm and the Al more fraction of the AlGaN layer 712 is set to 0.25. Similar to real devices, the AlGaN transition layer and AlN nucleation layer between GaN buffer and Si substrate are also taken into account in our simulation to reveal vertical leakage and breakdown behavior of both the SSDF HEMT 703 and conventional HEMTs. Also, physical properties such as spontaneous and piezoelectric polarization, unintentional buffer doping, high field saturation and impact ionization have also been taken into account.

Referring to FIG. 8, comprising FIGS. 8A and 8B, graphs 800, 820 of device characteristics of the SSDF III-nitride HEMT in accordance with the second embodiment are plotted. FIG. 8A depicts the graph 800 of barrier thickness 802 versus two-dimensional electron gas (2 DEG) conduction channel thickness 804 of the SSDF III-nitride HEMT 703 in order to show the 2 DEG carrier density within the AlGaN/GaN hetero junction 706 with different AlGaN barrier 712 thicknesses along the trace 806. Referring to FIG. 8B, the graph 820 plots a conduction band energy profile of the AlGaN/GaN hetero junction 706 at different AlGaN barrier 712 thicknesses (see traces 822, 824, 826, 828, 830).

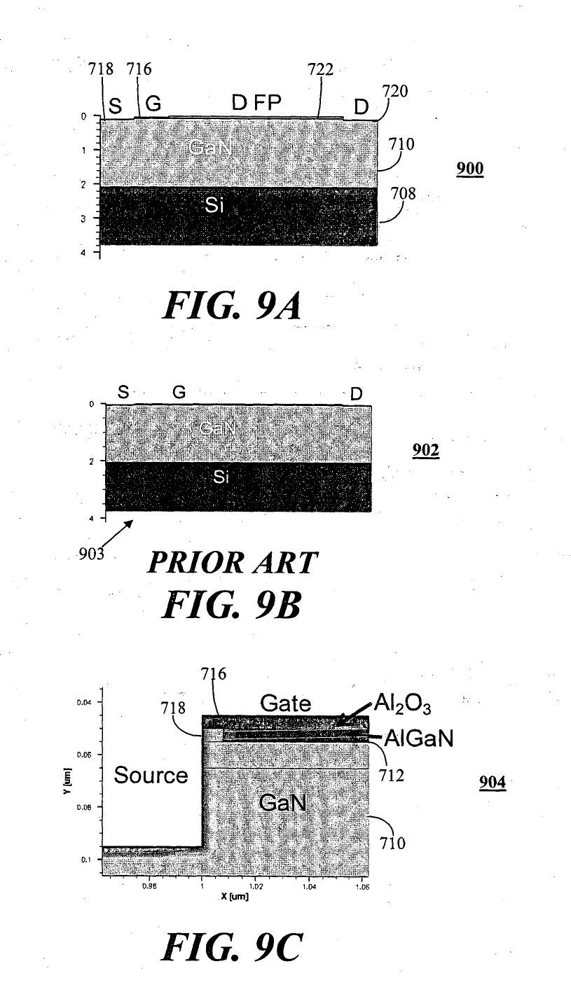

FIG. 9, comprising FIGS. 9A, 9B and 9C, illustrates schematic cross section views of the SSDF HEMT device 703 and a conventional HEMT device. FIG. 9A is a schematic cross section 900 of the SSDF HEMT device 703. FIG. 9B is a schematic cross section 902 of a conventional HEMT 903. And, FIG. 9C is a schematic cross section 904 of the SSDF HEMT device 703 zooming in on the source region 718 and the gate region 716 of the SSDF HEMT device 703.

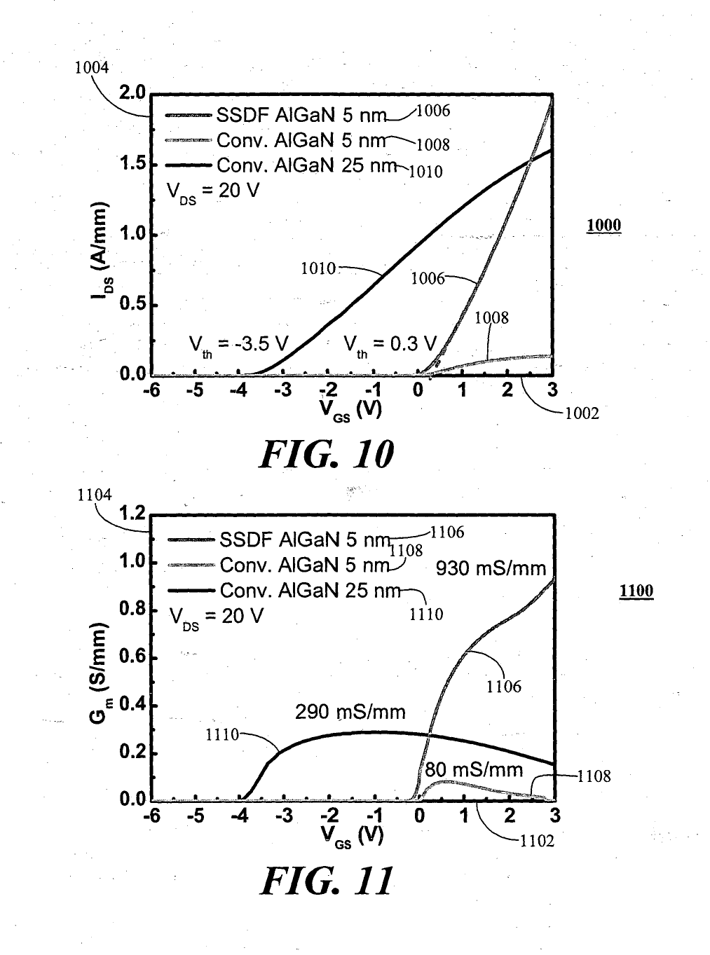

The I-V characteristics of the SSDF HEMT device 703 and conventional HEMT devices 903 are shown in FIGS. 10 to 13. Referring to FIG. 10, a graph 1000 in linear scale of gate-source voltage 1002 versus drain-source current 1004 of the SSDF HEMT device 703 and conventional HEMT devices 903 are plotted on traces 1006, 1008 and 1010. The simulated I_{DS}-V_{GS} transfer characteristics of the SSDF HEMT device 703 with a five nm AlGaN barrier layer 712 is shown on the trace 1006. And the simulated I_{DS}-V_{GS} transfer characteristics of the conventional HEMT devices 903 with a five nm and a twenty-five nm AlGaN barrier are shown on the traces 1008 and 1010, respectively. As can be seen from the traces 1006 and 1008, respectively, the Vₜₕ of the SSDF HEMT device 703 and the conventional HEMT devices 903 with the five nm AlGaN barrier layer can be shifted to positive (i.e., to +0.3 V), indicating true normally-off operation. However, the conventional HEMT device 903 with the five nm AlGaN barrier layer can hardly be turned on as evidenced by trace 1008. Furthermore, the SSDF HEMT device 703 shows superior ON state current driving capability, even better than the conventional HEMT device 903 with the twenty-five nm AlGaN barrier layer.

Referring next to FIG. 11, a graph 1100 in linear scale of gate-source voltage 1102 versus gate transconductance 1104 of the SSDF HEMT device 703 and conventional HEMT devices 903 are plotted on traces 1106, 1108 and 1110. The simulated Gₘ-V_{Gs} transconductance characteristics of the SSDF HEMT device 703 with a five nm AlGaN barrier layer 712 is plotted on the trace 1106. The simulated Gₘ-V_{Gs} transconductance characteristics of conventional HEMT devices with five nm and twenty-five nm AlGaN barrier layers are plotted on traces 1108 and 1010, respectively. Those skilled in the art will realize that the graph 1100 evidences that by implementing the unique device structure in accordance with the second embodiment, the SSDF native-off HEMT device 703 can deliver greater than three times the Gₘ as compared to conventional HEMT devices, indicating that the SSDF HEMT device 703 provides special advantages for ultra high speed and high gain electronics applications.

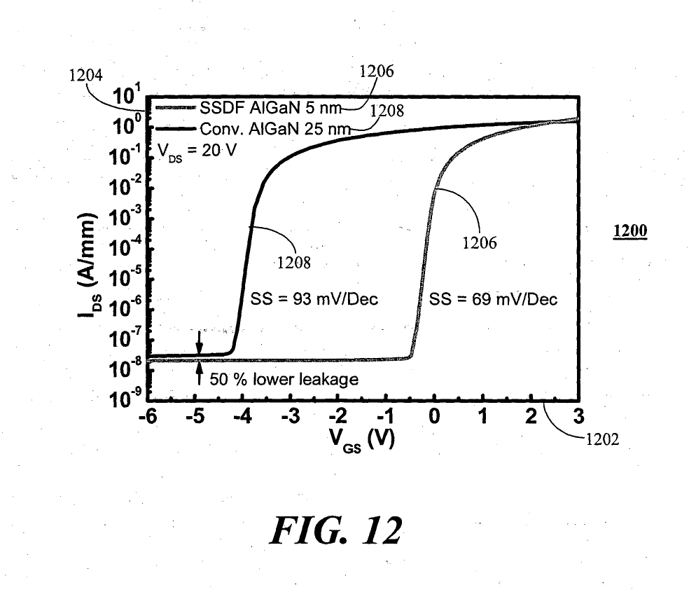

Turning next to FIG. 12, a graph 1200 in log scale of gate-source voltage 1202 versus drain-source current 1204 of the SSDF HEMT device 703 and conventional HEMT devices 903 are plotted on transfer curves 1206 and 1208, respectively. The characteristics of the SSDF HEMT device 703 with a five nm AlGaN barrier layer 712 are plotted on the curve 1206. The characteristics of a conventional HEMT device 903 with a twenty-five nm AlGaN barrier layer are plotted on the curve 1208. Due to the effective gate control of the SSDF HEMT device 703 with the thin AlGaN barrier layer 712, fifty per cent lower off-state leakage current (e.g., ˜10 nA/mm) and a higher sub-threshold swing (i.e., 69 mV/Dec compared to the 93 mV/Dec of the conventional HEMT) can beneficially be achieved.

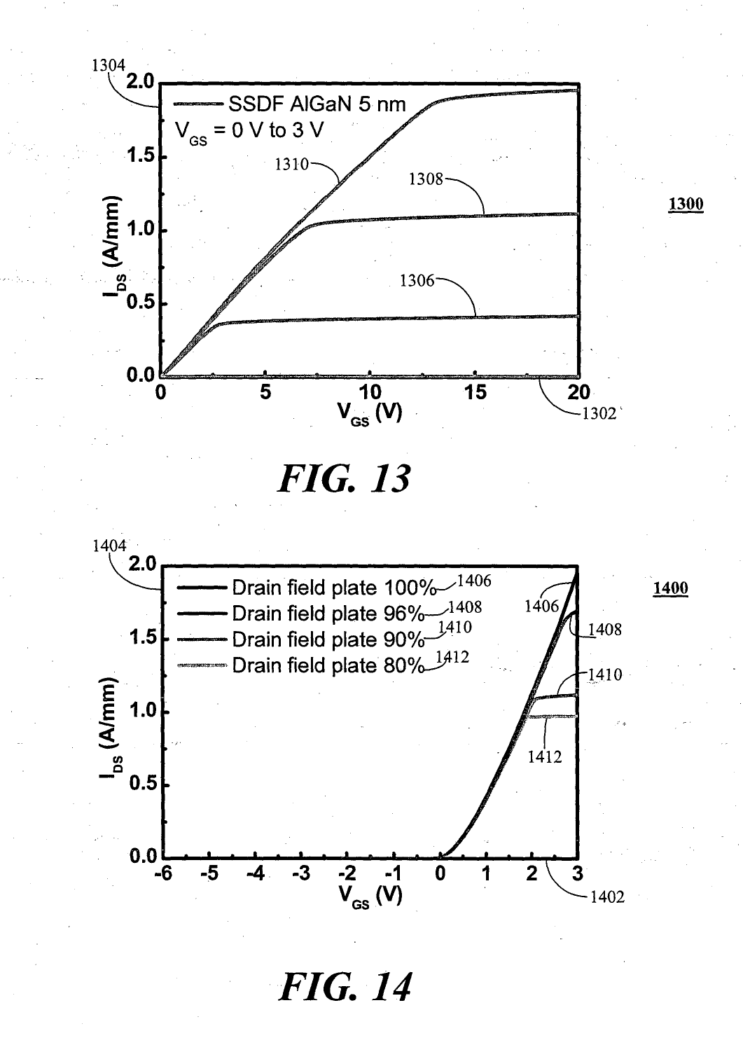

Referring next to FIG. 13, a log scale graph 1300 of gate-source voltage 1302 versus drain-source current 1304 of the SSDF HEMT device 703 with a five nm AlGaN barrier layer 712 is plotted on traces 1306, 1308 and 1310. The output voltage profile of the SSDF HEMT device 703 on traces 1306, 1308 and 1310 shows good linearity.

The impact of the drain field plate 722 (FIG. 7) is shown in FIG. 14. The drain field plate 722 is used to enhance the current driving capability of the SSDF native-off HEMT 703 in the ON state and provide uniform electric field distribution along the 2 DEG channel. FIG. 14 depicts a graph 1400 of gate-source voltage 1402 versus drain-source current 1404 of the SSDF HEMT device 703 output characteristics with different drain field plate 722 coverages on top of the channel between the gate 716 and the drain 720. Drain field plate 722 coverages of 100%, 96%, 90% and 80% are plotted on curves 1406, 1408, 1410, 1412, respectively. As can be seen from the graph 1400, without full coverage of by the drain field plate 722, in the ON state the drain current will saturate the 2 DEG channel and limit the SSDF HEMT device performance. For example, with 80% drain field plate coverage as plotted on the curve 1412, the maximum ON current density is only half of the maximum ON current density for the 100% drain field plate coverage as plotted on the curve 1406.

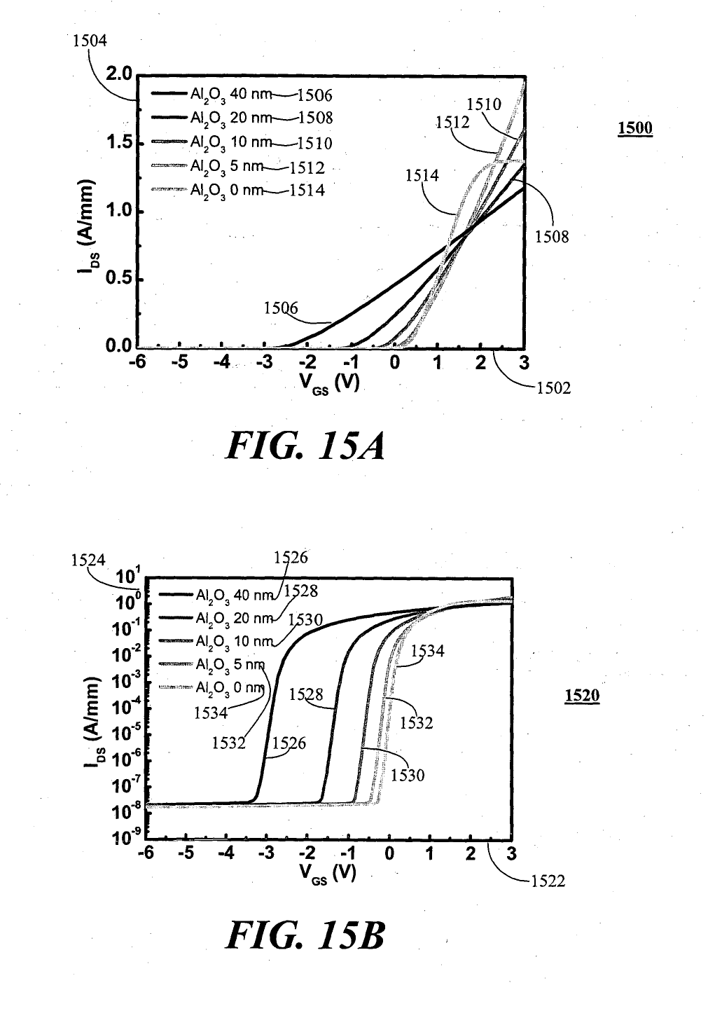

In the SSDF HEMT device 703, the gate dielectric layer 726 (i.e., Al₂O₃) is deposited between the gate 716 and the AlGaN barrier layer 712 to block gate leakage current, isolate the gate 716 from the source electrode 718, and tune the device threshold voltage. In order to investigate the contribution of gate dielectric, device simulation of SSDF native-off HEMT with Al₂O₃ gate dielectric thickness is carried out. FIG. 15, comprising FIGS. 15A and 15B, illustrates graphs 1500, 1520 of gate-source voltage 1502, 1522 versus drain-source current 1504, 1524 of the SSDF HEMT device 703 with different gate dielectric 726 thicknesses, wherein the graph 1500 is in linear scale and the graph 720 is in log scale. The simulated I_{GS}-V_{DS} output characteristics in linear scale for the SSDF HEMT device 703 having Al₂O₃ gate dielectric 726 thicknesses forty nm, twenty nm, ten nm, five nm and zero nm are plotted on the curves 1506, 1508, 1510, 1512 and 1514, respectively. Similarly, the simulated I_{GS}-V_{DS} output characteristics in log scale for the SSDF HEMT device 703 having Al₂O₃ gate dielectric 726 thicknesses forty nm, twenty nm, ten nm, five nm and zero nm are plotted on the curves 1526, 1528, 1530, 1532 and 1534, respectively. The simulation results the graphs 1500, 1520 illustrate that, without the gate dielectric layer 726, the SSDF HEMT device 703 will suffer large gate leakage at high V_{GS} bias thereby limiting the ON state current. In addition, a thicker Al₂O₃ gate dielectric layer 726 will provide more negative Vₜₕ. Thus, the SSDF HEMT device 703 can provide both normally-on and normally-off mode operation with Vₜₕ ranging from −2.4 V to +0.3 V, thereby advantageously providing greater flexibility in applications for a variety of circuit applications.

The device performance comparison between the SSDF native-off HEMT device 703 and a conventional HEMT device is summarized in Table 1.

TABLE 1

| | SSDF | Conventional |
|---|---|---|
| I_{OFF} (nA/mm) | 19 | 45 |
| | @ V_{DS} = 50 V | @ V_{DS} =10 V |
| I_{ON} (A/mm) | 1.96 | 1.60 |
| | @ V_{GS} = 3 V | @ V_{GS} = 3 V |
| I_{ON}/I_{OFF} | 10⁸ | 10⁷ |
| SS (mV/Decade) | 69 | 93 |
| Vₜₕ (V) | +0.3 | −3.5 |
| Gₘ (mS/mm) | 930 | 290 |

As can be seen from Table 1, the III-nitride SSDF native-off HEMT device 703 with the thin AlGaN barrier layer 712, the surface passivation layer 724, the self-aligned source ohmic contact 718 and the drain field plate 722 is presented herein. Since the SSDF HEMT device 703 is directly fabricated on the native-off AlGaN/GaN hetero-structure 706 grown by MOCVD, no special process, such as gate recess, fluorine treatment or p-type doping is needed for normally-off transistor fabrication. Thus, advantages, such as good uniformity, defect free, fabrication ease, large current driving capability (e.g., >1.5 A/mm at V_{GS}=3 V), low leakage (e.g., 10 nA/mm), high transconductance (e.g., >900 mS/mm), small sub-threshold swing (e.g., <70 mV/Dec), high Iₒₙ/I_{off} ratio (e.g., 10⁸) and normally-off operation (e.g., Vₜₕ=+0.3V) can be achieved, indicating good industry applicability for high efficiency power electronics, RF applications and enhancement/depletion mode logic circuits.

In accordance with a third embodiment, a novel device structure, which is combined with a surface state energy level modulated (SSEM) layer, a negative charge doped gate dielectric and a source field plate, is provided based on a MOCVD grown AlGaN/GaN hetero junction device. The SSEM normally-on/off III-nitride HEMT device in accordance with this third embodiment possesses unique characteristics allowing it to realize current collapse freedom, high stability, high OFF state breakdown voltage (e.g., 70 V/μm), high ON state current driving capability (e.g., >1.2 A/mm), low leakage (e.g., one nA/mm), high speed, high temperature tolerance and threshold voltage tunability.

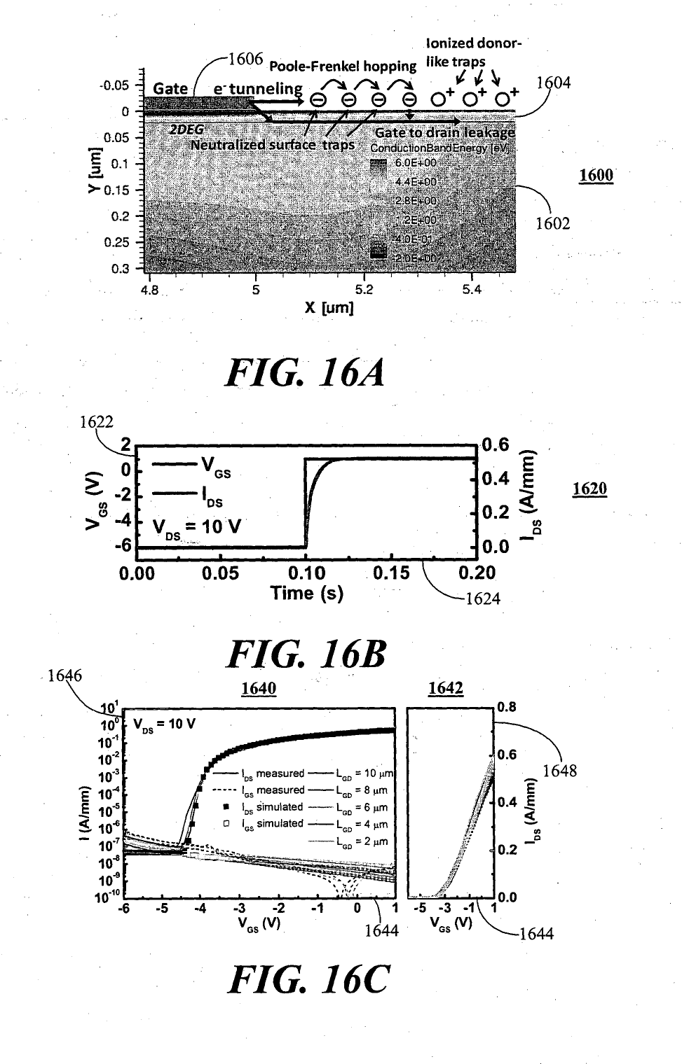

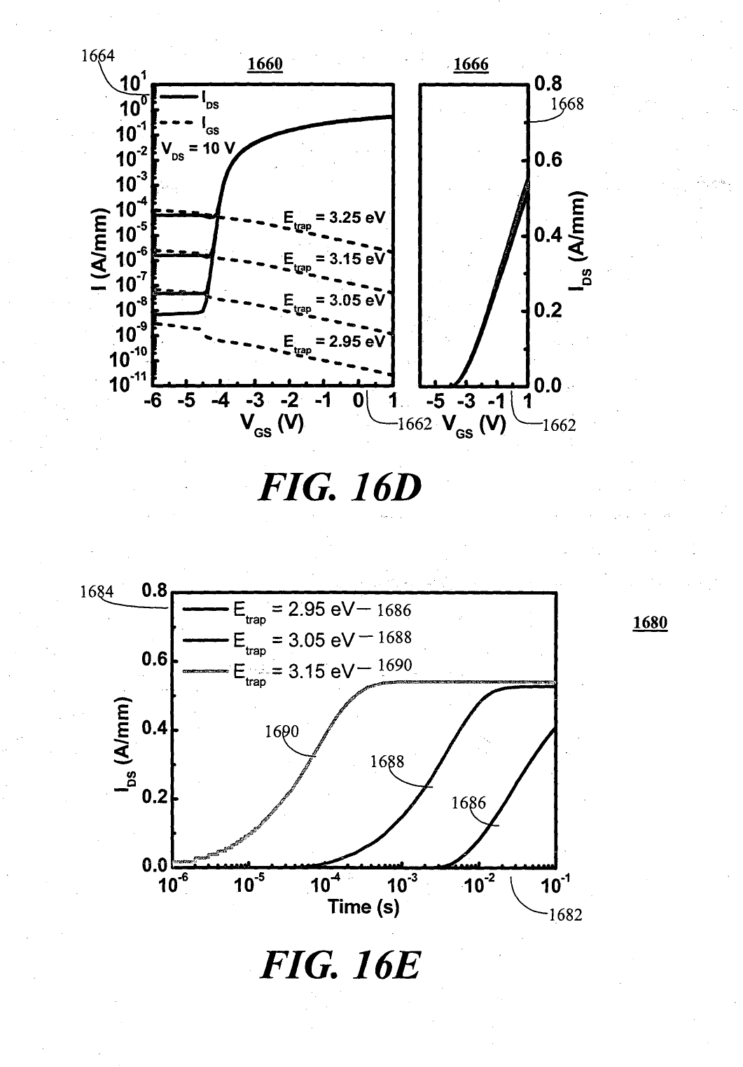

It has been found that surface donor-like traps arising from the Ga adatom dangling bonds which are beneficial to 2 DEG channel formation have significant impact on channel conductance modulation via charging/discharging, leading to current collapse and contributing to suppression of Schottky gate tunneling leakage. The surface trapping/detrapping mechanism of III-nitride HEMTs is illustrated in FIG. 16, comprising FIGS. 16A to 16E. Referring to FIG. 16A, a simulated conduction band profile and schematic view 1600 of gate electron tunneling and surface trapping at V_{GS}=−6 V and V_{DS}=10V is depicted. Along the GaN layer 1602 surface, the trapped electrons can transport via the Poole-Frankel electron hopping effect. The neutralized surface traps together with the strong polarization charges on the GaN cap surface can significantly deplete the electron carriers in the 2 DEG channel 1604, leading to voltage screening effects such as “virtual gate” and further suppressing the electron tunneling from a gate 1606 to the 2 DEG channel 1604.

During dynamic switching of III-nitride HEMTs, the current collapse effect will affect the output response of the transistors, as shown in FIG. 16B. FIG. 16B depicts a graph 1620 of a transient simulation of operation of AlGaN/GaN HEMT devices with V_{GS} 1622 jumping from −6 V to 1 V at 0.1 second and holding for another 0.1 second, time being plotted along the x-axis 1624. The time constant for surface trapping/detrapping and the response of the drain current is ˜10 ms. Compared to conventional results (e.g., 3 s) of bare AlGaN/GaN, the extracted speed of the surface trapping/detrapping from this simulation is faster, owing to an additional GaN cap layer on top of the AlGaN barrier in accordance with the third embodiment which will form an upper channel and enhance the surface electron transporting.

Based on this physical understanding of the third embodiment, a hybrid TCAD and SPICE model describing the dynamic switching behavior of III-nitride HEMTs is calibrated by using experimental measured data from AlGaN/GaN HEMTs fabricated using an Au-based process, as shown in FIG. 16C. FIG. 16C depicts graphs 1640, 1642 of measured and simulated gate-source voltage 1644 versus current 1646 (gate-source current I_{GS} and drain-source current I_{DS}) (in the log scale graph 1640) and drain-source current (I_{DS}) 1648 (in the linear scale graph 1642) for characteristics various gate drain lengths (L_{GD}) between 2 μm and 10 μm of the AlGaN/GaN HEMT device in accordance with the third embodiment. The source/drain ohmic contact resistance is set to 2 Ω·mm according to measured results from the transfer length method (TLM) structures. Excellent agreement of both I_{DS} and I_{GS} can be achieved between the TCAD simulation and experimental measurements as seen from the graph.

According to the device simulation, it has been found that the higher the surface trap energy level is the less surface traps will be charged and discharged by electrons tunneling from the gate electrode, leading to less surface trapping/detrapping, less source/drain voltage screen, less current collapse and faster device response as can be seen from FIGS. 16D and 16E. Referring to FIG. 161), a log scale graph 1660 of gate-source voltage 1662 versus current 1664 (gate-source current I_{GS} and drain-source current I_{DS}) and a linear scale graph 1666 of gate-source voltage 1662 versus drain-source current (I_{DS}) 1668 for various surface traps of the AlGaN/GaN HEMT device in accordance with the third embodiment are depicted. The simulated I_{DS}-V_{GS} and I_{GS}-V_{GS} characteristics of the AlGaN/GaN HEMTs in accordance with the third embodiment and having surface traps located at 2.95 to 3.25 eV above the valance band and L_{GD}=10 μm are plotted in the graphs 1660, 1666. With a high trap energy level, it is difficult for the donor-like traps to be neutralized by electrons, tunneling from the gate electrode, leading to a weaker screening effect. Therefore, the voltage drop between the gate and the adjacent 2 DEG channel of the AlGaN/GaN HEMTs in accordance with the third embodiment will be higher thereby providing stronger gate electron tunneling. FIG. 16E depicts a graph 1680 of time 1682 versus drain-source current 1684 for the various surface traps of the AlGaN/GaN HEMT device in accordance with the third embodiment. The simulated I_{DS} response of the AlGaN/GaN HEMTs in accordance with the third embodiment with surface traps located at 2.95 eV, 3.05 eV and 3.15 eV above the valance band (with L_{GD}=10 μm) is shown on traces 1686, 1688 and 1690, respectively, in the graph 1680.

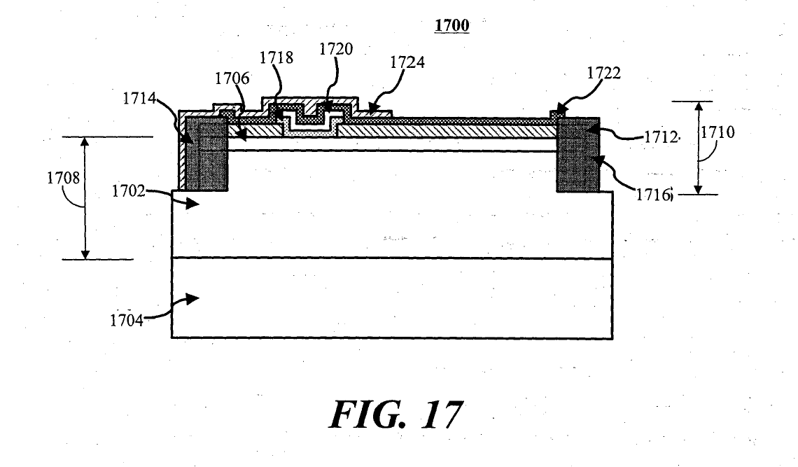

FIG. 17 illustrates a schematic cross section view 1700 of a surface state energy level modulated (SSEM) HEMT device in accordance with the third embodiment. A GaN buffer layer 1702 is formed on a substrate 1704 (e.g., Si, sapphire or SiC) by MOCVD. An AlGaN barrier layer 1706 is formed (also by MOCVD) on the GaN buffer layer 1702 thereby forming an AlGaN/GaN hetero-junction device 1708. A surface state energy level modulation (SSEM) HEMT transistor 1710 is formed on the AlGaN/GaN hetero junction device 1708 and includes a SSEM layer 1712, a Ti/Al based source ohmic contact 1714, a Ti/Al based drain ohmic contact 1716, a negative charged gate dielectric 1718 (e.g. Al₂O₃ with [F]), a gate metal contact 1720 (e.g. Ni), a passivation layer 1722 (e.g. Si₃N₄,), and a source field plate 1724 (e.g. Ti or Al).

The SSEM layer 1712 is implemented in the III-nitride HEMT 1700 in accordance with the third embodiment to raise the energy level of surface traps and thus suppress the surface trapping/detrapping during dynamic switching. This can be realized by, growing/depositing an AlGaN cap layer with a high Al mole-fraction, AlN passivation and negative charge doped passivation on top of the standard AlGaN/GaN hetero junction 1708. In addition, the SSEM layer 1712 (e.g. the AlGaN cap layer with high Al mole-fraction or the AlN passivation), can further enhance the spontaneous and piezoelectric polarization strength within the AlGaN/GaN hetero-junction, thereby contributing to higher electron carrier concentration in the 2 DEG channel making the III-nitride HEMTs in accordance with the third embodiment able to deliver lower ON resistance and higher current driving capability.

The negative charge doped gate dielectric layer 1718 (e.g. Al₂O₃ with [F]) is deposited under the gate dielectric layer, to block the electron tunneling current from the gate to both the surface traps and the 2 DEG channel. Thus, without electron supplying, rare donor-like surface traps on top of the AlGaN/GaN hetero-structure 1708 can be neutralized, even at large V_{DG} or V_{SG} bias, leading to negligible current collapse and stable dynamic operation. Meanwhile, the negative charge doping under the gate can further raise the conduction band of the hetero junction under the gate electrode, depleting the free electron carriers in the 2 DEG channel and thereby delivering flexible threshold voltage modulation capability (from −3 V to 2 V). This threshold voltage modulation capability can advantageously be used to achieve monolithic integrated normally-on and normally-off III-nitride power electronic platforms.

Also, the novel source field plate 1724 is used in the SSEM HEMT 1700 in accordance with the third embodiment to uniformly distribute the electrical field along the 2 DEG channel and enhance the breakdown voltage. In the SSEM HEMT 1700, since surface trapping/de-trapping has been suppressed, the screen effect of the drain/source voltage induced by the surface trap charging/discharging at the edge of a gate electrode in a conventional HEMT will not occur, thereby preventing further reduction of the peak electrical field. Therefore, in order to obtain a high breakdown voltage, the source field plate 1724 is implemented to replace this natural screening effect in the SSEM HEMT 1700 to avoid early impact ionization induced avalanche breakdown. The source field plate 1724, when connected to the source electrode 1714, can provide fast gate charging and switching capability and more stable dynamic channel conductance as compared to a gate field plate.

The passivation layer 1722 is deposited on top of the SSEM layer 1712 to block an electrical short between the source field plate 1724 and the III-nitride hetero-structure 1708 surface. Optimization of the passivation layer 1722 thickness can achieve low parasitic Cgs capacitance, good electrical field uniformity and high breakdown voltage. In addition, the passivation layer 1722 (e.g. a Si₃N₄ layer) can further compensate some of the surface states on top of the III-nitride material and enhance the dynamic operation stability of the III-nitride HEMT 1700.

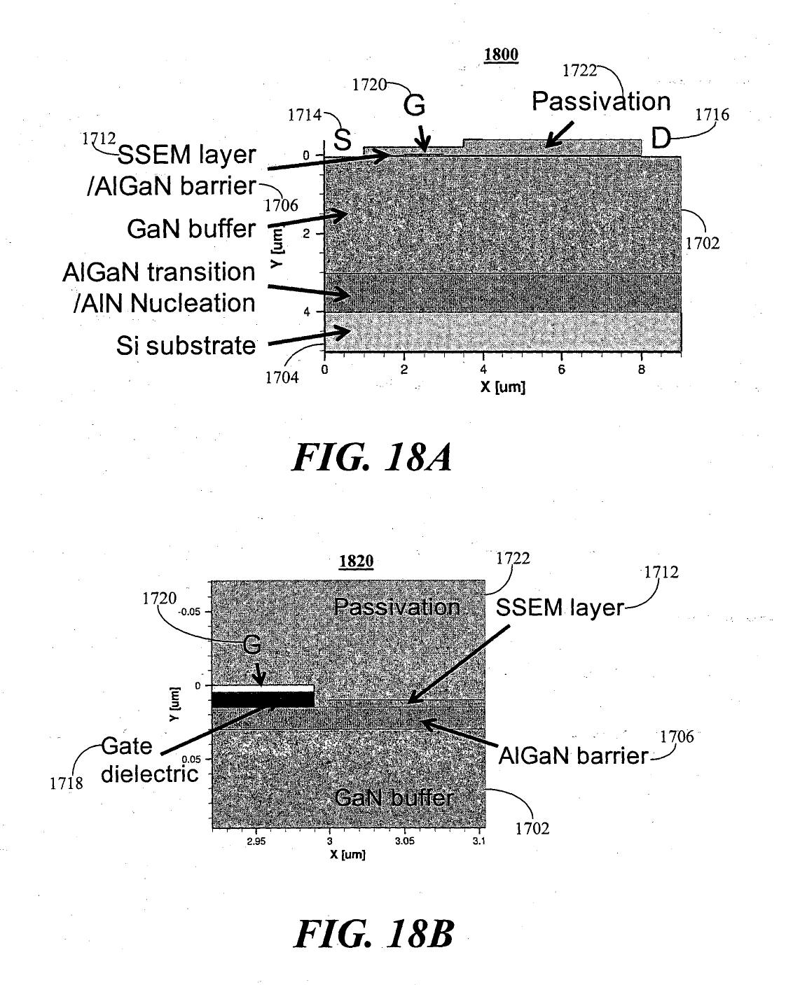

In order to characterize the device performance of the SSEM III-nitride HEMT 1700, device simulations of the SSEM III-nitride HEMT 1700 with surface negative charge doped layer or high Al mole-fraction AlGaN cap layer as the SSEM layer 1712 were performed using a Senturaus device simulation program from Synopsys, Inc. of Mountain View, Calif. USA. A conventional HEMT was also modeled as a reference since both SSEM HEMTs and conventional HEMTs have the same device dimensions and use the same physical models (e.g., polarization, unintentional background doping (˜10¹⁶ cm⁻³), AlGaN transition layer, and MN nucleation layer). The device model structure of the SSEM HEMT in accordance with the third embodiment is shown in FIG. 18, including FIGS. 18A and 18B. FIG. 18A is a schematic cross section view 1800 of the SSEM III-nitride HEMT device in accordance with the third embodiment and FIG. 18B is a zoom-in schematic cross section view 1820 of the gate 1720 region of the SSEM III-nitride HEMT device in accordance with the third embodiment.

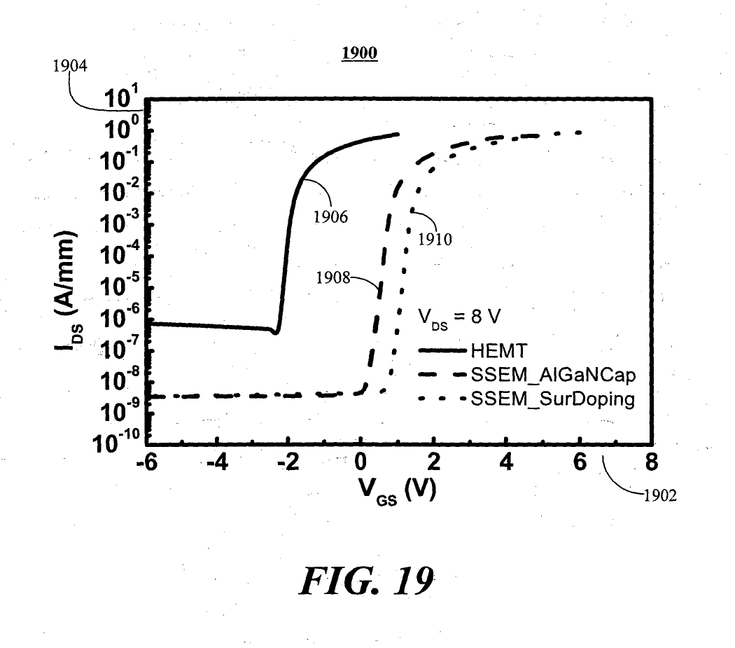

The simulated I-V characteristics of the SSEM III-nitride HEMT 1700 and a conventional HEMT are shown in FIG. 19. FIG. 19 illustrates a graph 1900 in log scale of gate-source voltage 1902 versus drain-source current 1904 of the SSEM III-nitride HEMT device 1700 in accordance with the third embodiment. The simulated I_{DS}-V_{GS} characteristics of the SSEM III-nitride HEMT device 1700 and a conventional HEMT at V_{DS}=8 V are shown in log scale in the graph 1900. As seen from comparing trace 1906 for a conventional HEMT and traces 1908, 1910 for the SSEM HEMT device 1700, the SSEM HEMT device 1700 can achieve lower leakage current (e.g., ˜1 nA/mm) and a positive threshold voltage (e.g., +1V) as compared to the conventional HEMT.

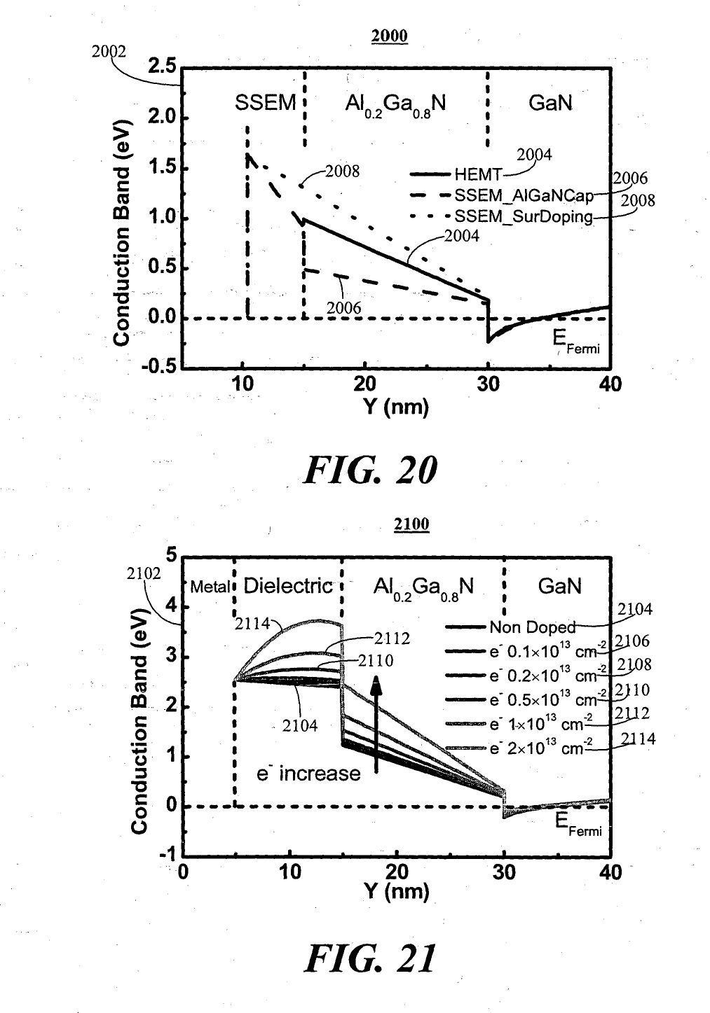

The calculated conduction band profiles of SSEM HEMTs in accordance with the third embodiment and conventional HEMTs in both a drift region (between the gate 1720 and the drain 1716) and a gated region are illustrated in FIGS. 20 and 21. FIG. 20 illustrates a graph 2000 of conduction band profiles 2002 between a gate and a drain for a conventional HEMT (trace 2004) and the gate 1720 and the drain 1716 for the SSEM III-nitride HEMT device 1700 (traces 2006 and 2008). As can be seen from FIG. 21, both a high Al mole-fraction AlGaN cap and surface doping can raise the surface energy level to greater than 0.5 eV, leading to less surface trapping/detrapping during switching. FIG. 21 illustrates a graph 2100 of conduction band profiles 2102 under the gate 1720 in SSEM III-nitride HEMT devices 1700 having various dopant levels (traces 2104, 2106, 2108, 2110, 2112 and 2114) of the negative charge doped gate dielectric layer 1718. FIG. 21 illustrates the CB profiles of SSEM HEMT under gate. From FIG. 21, it can be seen that heavier dielectric negative charge doping can result in a higher gate dielectric barrier, leading to better gate leakage blocking capability.

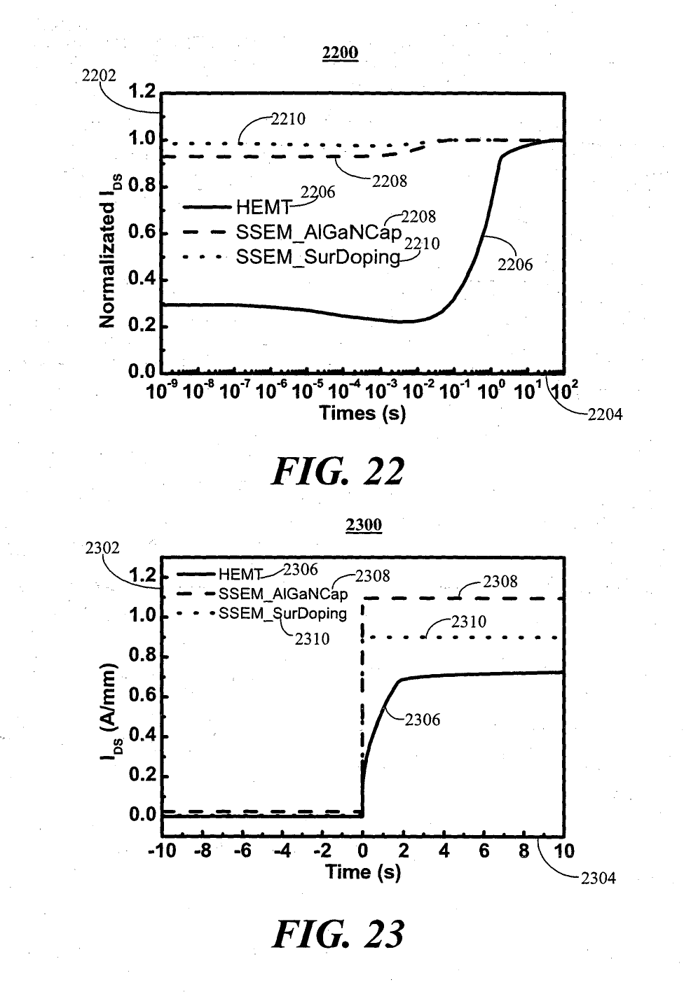

In order to investigate the dynamic behavior of the SSEM HEMT device 1700 during switching, transient simulation of transistors pulsed from 0V (an OFF state) to 5V (an ON state) is shown in FIGS. 22 and 23 and compared to the transient responses of conventional HEMTs from −3V to 1V. FIG. 22 illustrates a graph 2200 in log scale of transient behaviors 2202 with the input gate bias jumped from an OFF state (0V for the SSEM HEMT device 1700, −3V for the conventional HEMT) to an ON state (5V for the SSEM HEMT device 1700, 1V for the conventional HEMT) at time 2204 equals zero seconds, the conventional HEMT plotted on trace 2206 and the SSEM III-nitride HEMT devices 1700 plotted on traces 2208 and 2210. FIG. 23 illustrates a graph 2300 in linear scale of transient behaviors 2302 with the input gate bias jumped from an OFF state (0V for the SSEM HEMT device 1700, −3V for the conventional HEMT) to an ON state (5V for the SSEM HEMT device 1700, 1V for the conventional HEMT) at time 2304 equals zero seconds, the conventional HEMT plotted on trace 2306 and the SSEM III-nitride HEMT devices 1700 plotted on traces 2308 and 2310. From the graphs 2200, 2300 it is apparent that when the gate bias suddenly jumps from an OFF state to an ON state, the output current of the SSEM HEMT devices 1700 can immediately increase following the input signal, even at the 10⁻⁹ second level, no lagging or delay is apparent, evidencing current collapse free operation of the SSEM III-nitride HEMT devices 1700.

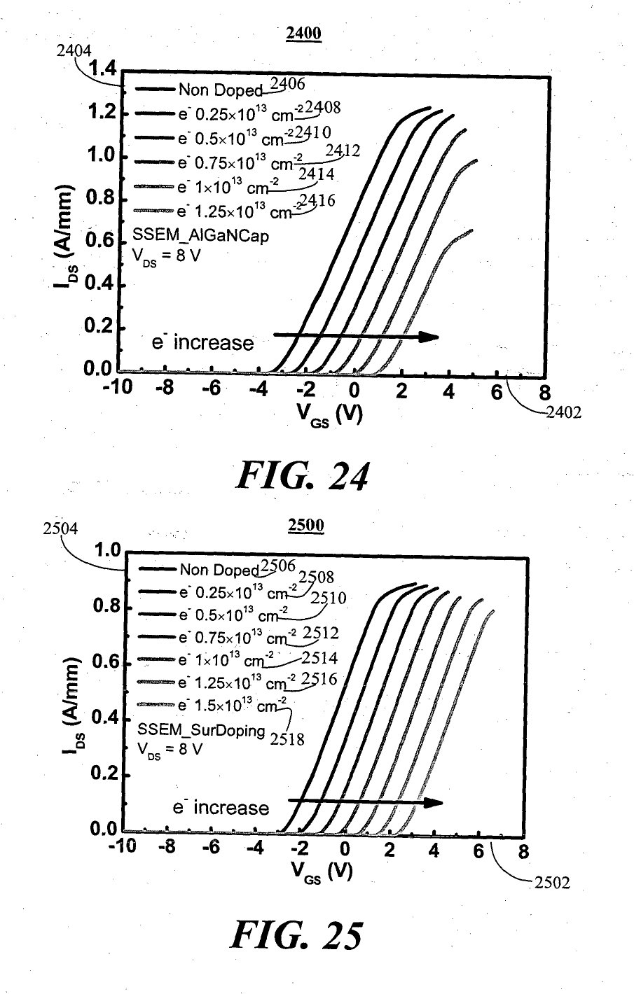

In addition, after doping in the gate dielectric layer 1718, negative charges will also be injected into the gate covered AlGaN barrier layer 1706, which will affect the threshold voltage of the SSEM HEMT device 1700. The transfer I-V characteristics of the SSEM HEMT devices with various negative charge doping levels under the gate 1720 are shown in FIGS. 24 and 25. FIG. 24 illustrates a graph 2400 of gate-source voltage 2402 versus drain-source current 2404 for SSEM III-nitride HEMT devices 1700 having a AlGaN cap layer 1706 of various high Al mole-fractions plotted on traces 2406, 2408, 2410, 2412, 2414 and 2416. FIG. 25 illustrates a graph 2500 of gate-source voltage 2502 versus drain-source current 2504 for SSEM III-nitride HEMT devices 1700 having various surface negative charge doping levels plotted on traces 2506, 2508, 2510, 2512, 2514, 2516 and 2518. FIGS. 24 and 25 indicate that the Vₜₕ can be modulated from ˜−3V to +2V by varying either the Al mole-fractions of the AlGaN cap layer 1706 (FIG. 24) or the surface negative charge doping levels (FIG. 25).

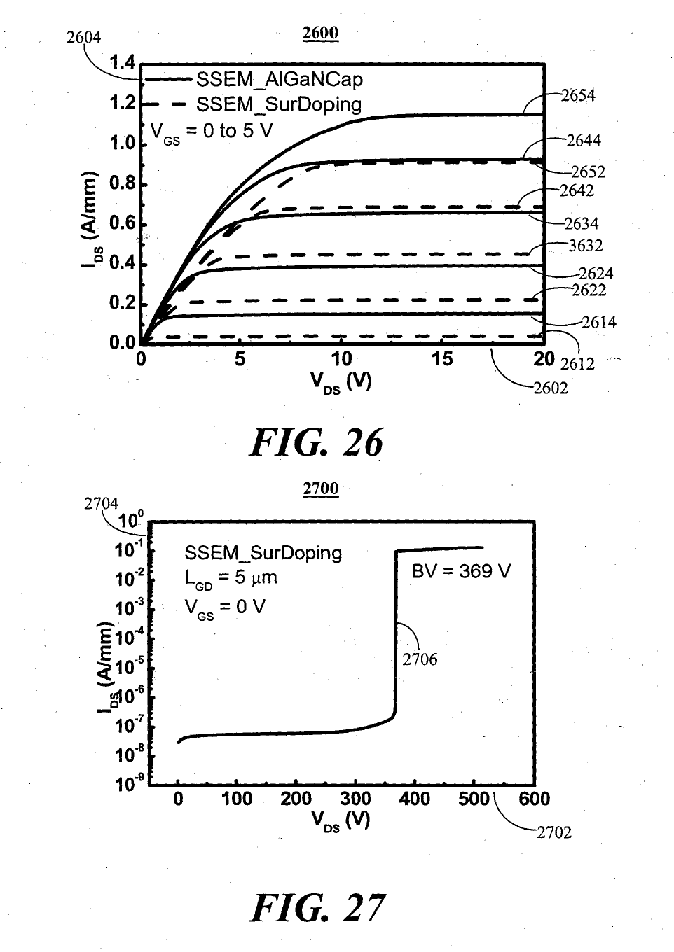

The I_{DS}-V_{DS} characteristics of SSEM HEMT devices 1700 in both the ON state and the OFF state are shown in FIGS. 26 and 27. FIG. 26 illustrates a graph 2600 in linear scale of gate-source voltage 2602 versus drain-source current 2604 for the SSEM III-nitride HEMT devices 1700 simulating the I_{DS}-V_{DS} characteristics of the SSEM III-nitride HEMT devices 1700. The gate-source voltage of the SSEM HEMT devices are varied from 0V to 1V (traces 2612 and 2614) to 2V (traces 2622 and 2624) to 3V (traces 2632 and 2634) to 4V (traces 2642 and 2644) to 5V (traces 2652 and 2654). FIG. 27 illustrates a graph 2700 in log scale of OFF state gate-source voltage 2702 versus drain-source current 2704 for the SSEM III-nitride HEMT devices 1700 formed using surface negative charge doping. The ON resistances of the SSEM HEMT devices are extracted from 5.4 to 7.2 Ω·mm and plotted on trace 2706. According to the simulation results in the graph 2702, the breakdown voltage is 369V with a L_{GD} of 5 μm. Finely designed source field plates 1724 (FIG. 17) can further improve the breakdown performance of the SSEM HEMT devices 1700.

The SSEM III-nitride HEMT device 1700 advantageously includes the surface state energy level modulation (SSEM) layer 1712, the negative charge doped gate dielectric layer 1718 and the source field plate 1724. The surface state energy level modulation layer 1712 is used to suppress surface trapping/detrapping as well as current collapse. The negative charge doped gate dielectric layer 1718 is deposited between the gate electrode 1720 and the AlGaN barrier layer 1706 to block the gate leakage current and further prevent current collapse. In addition, the source field plate 1724 is implemented to enhance the breakdown performance and stability of SSEM HEMT. Threshold voltage modulation by tuning negative doping in the gate dielectric layer 1718 can be achieved for normally-on/normally-off monolithic integration on the same AlGaN/GaN hetero-structure 1708 epitaxial wafer.

In accordance with a fourth embodiment, a HEMT device structure 2802 is provided which combines a lateral negative charge assisted super junction (NSJ) 2806 and an interval-finger gate field plate 2808 in a HEMT transistor formed on an AlGaN/GaN hetero junction 2804. The NSJ III-nitride HEMT device 2800 possesses unique characteristics which allow it to realize high off-state breakdown voltage (e.g., 200 V/μm), high ON state current driving capability (e.g., >1.2 A/mm), low leakage (e.g., 10 nA/mm), high speed and high temperature tolerance. In addition, both normally-on and normally-off NSJ III-nitride transistors can be monolithically integrated on the same standard AlGaN/GaN hetero-structure 2804 epitaxial wafer using negative charge doping technology.

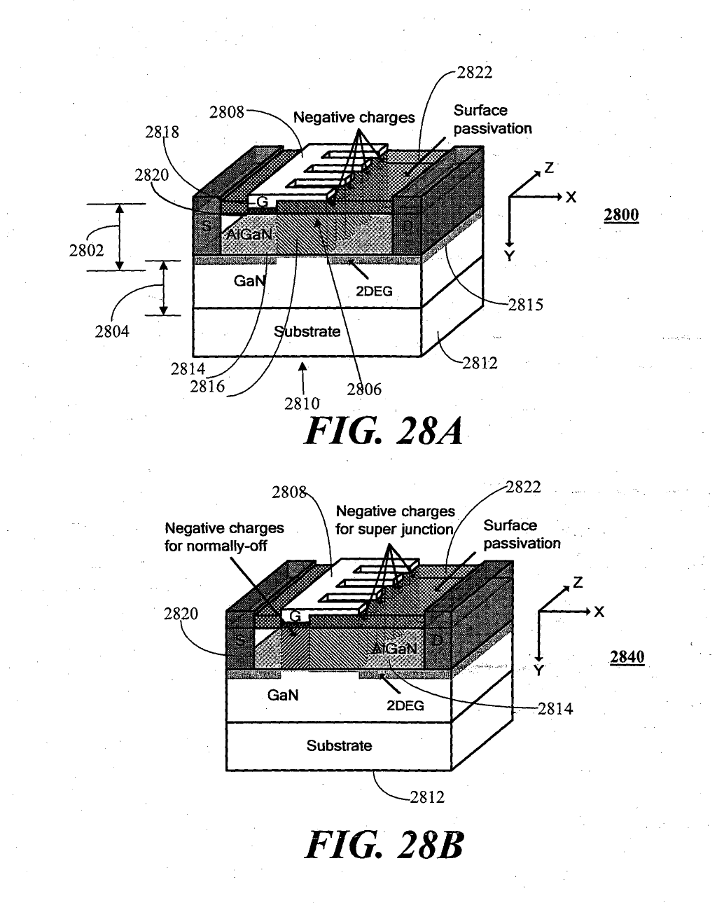

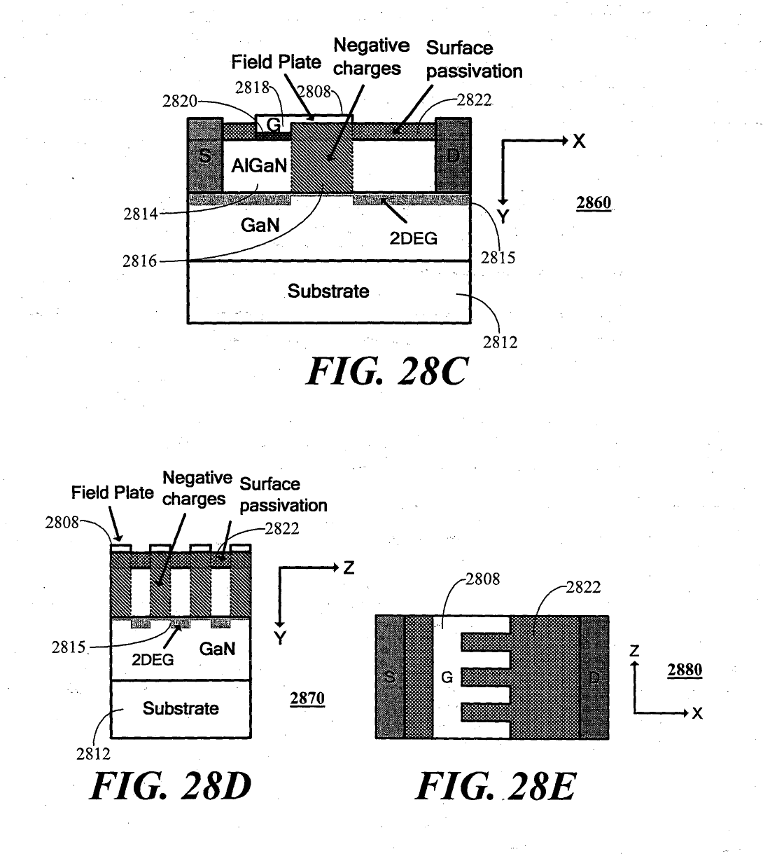

Referring to FIG. 28, two-dimensional and three-dimensional schematic cross-section views of a NSJ III-nitride HEMT device 2810 in accordance with the fourth embodiment is illustrated. FIG. 28A is a three-dimensional perspective view 2800 of a normally ON NSJ III-nitride HEMT device 2810. FIG. 28B is a three-dimensional perspective view 2830 of a normally OFF NSJ III-nitride HEMT device 2840. And FIG. 28C is a two-dimensional x-y cross section side view 2860 of the normally ON NSJ III-nitride HEMT device 2810, FIG. 28D is a two-dimensional z-y cross section side view 2870 of the normally ON NSJ III-nitride HEMT device 2810, and FIG. 28E is a two-dimensional x-z cross section top view 2880 of the normally ON NSJ III-nitride HEMT.

As can be seen from FIG. 28, the NSJ III-nitride HEMT 2802 is fabricated on the AlGaN/GaN hetero junction structure 2804 which is grown on a substrate layer 2812 (e.g. Si, sapphire or SiC) by MOCVD. The lateral negative charge assisted super junction (NSJ) 2806 is formed by using interval ion implantation with strong electron negativity ions (e.g. fluorine, oxygen). After ion implantation, negative charges (e⁻) 2816 are introduced into the AlGaN barrier layer 2814 along the drift region. In this manner, electron carriers in a 2 DEG channel 2815 under the e⁻ doping area will be partially depleted leading to a lower 2 DEG concentration. In the OFF state, the low 2 DEG concentration region below the negative fixed charges can easily be fully depleted, thereby enabling a lower peak electrical field and a higher breakdown voltage.

On top of the e⁻ doping area 2816, the interval-finger gate field plate 2808 is deposited to enhance the controllability of the NSJ 2806. In the OFF state, when the gate electrode 2818 is negatively biased, there will be a lateral voltage drop between the plate covered (e⁻ doped) region 2816 and the uncovered (non-doped) drift regions in the AlGaN barrier layer 2814, which leads to a lateral pinch-off of the 2 DEG channel, further extending the 2 DEG channel depletion. In the ON state, free electron carriers will accumulate in the drift region due to the positively biased gate field plate 2808, thereby fully turning ON the 2 DEG channel. This results in good ON state current driving capability.

A gate dielectric layer 2820 (e.g. Al₂O₃) is used in the NSJ III-nitride HEMT device 2810 to block the gate 2818 leakage current and protect the gate 2818 contact interface. Thus, even at high drain voltage bias or high temperature, the Schottky barrier tunneling and thermionic emission at the gate electrode 2818 is negligible. This effect further improves the OFF state breakdown performance of the NSJ HEMT device 2810 due to the avalanche breakdown at high electrical field being sensitive to the leakage current density. A surface passivation layer 2822 is formed over the e⁻ doping areas.

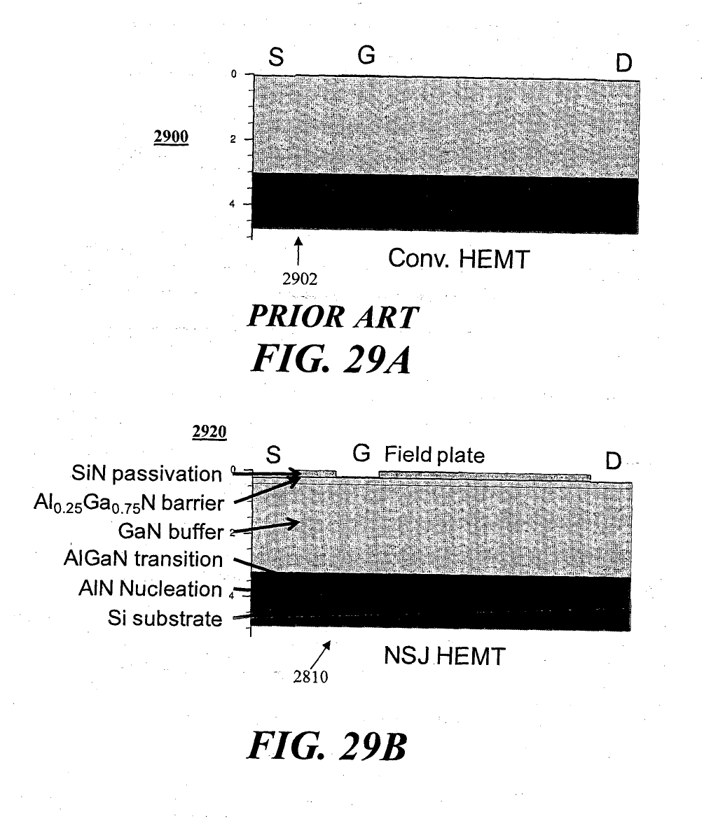

In order to characterize the device performance of the NSJ III-nitride HEMT device 2810, device simulations of the NSJ III-nitride HEMT device 2810 and a conventional HEMT device 2902 were generated by using the Senturaus device simulation program. Referring to FIG. 29, including FIGS. 29A and 29B, schematic cross section views 2900, 2920 of the HEMTs 2810, 2902 are illustrated. FIG. 29A is a schematic cross section view 2900 of a conventional HEMT device 2902 and FIG. 29B is a schematic cross section view 2920 of the NSJ III-nitride HEMT device 2810 in accordance with the fourth embodiment.

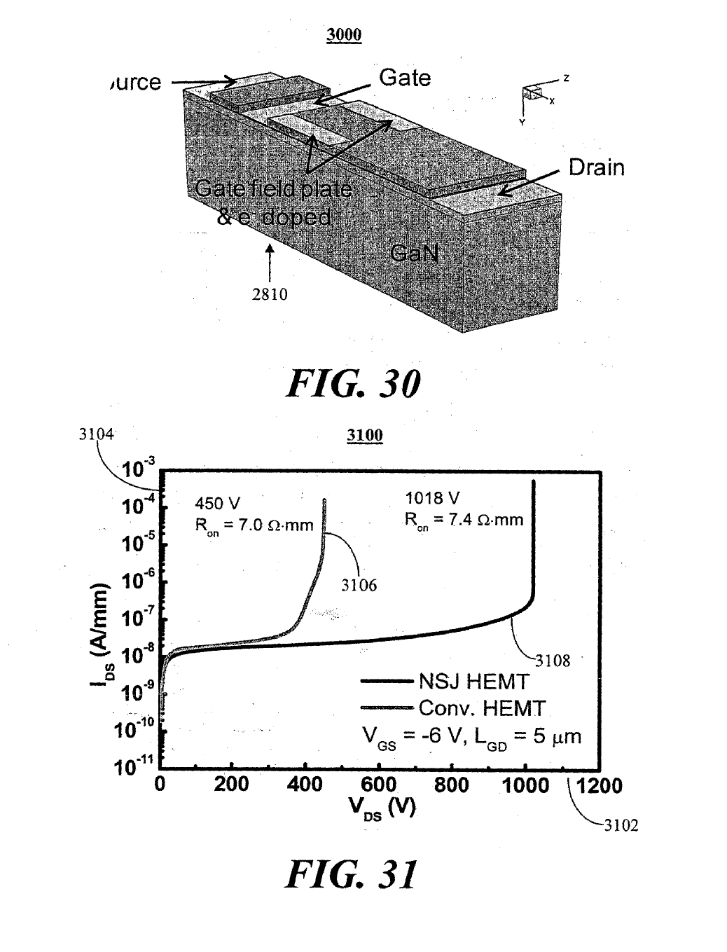

Both the NSJ III-nitride HEMT device 2810 and the conventional HEMT device 2902 have the same device dimensions and use the same physical models (e.g., polarization, unintentional background doping (˜10¹⁶ cm⁻³), AlGaN transition layer, AlN nucleation layer). In order to model the lateral channel modulation of the super junction, a three-dimensional device simulation of the NSJ III-nitride HEMT device 2810 has also been carried out, as shown in FIG. 30. FIG. 30 illustrates a three-dimensional perspective view 3000 of the NSJ III-nitride HEMT device 2810 in accordance with the fourth embodiment.

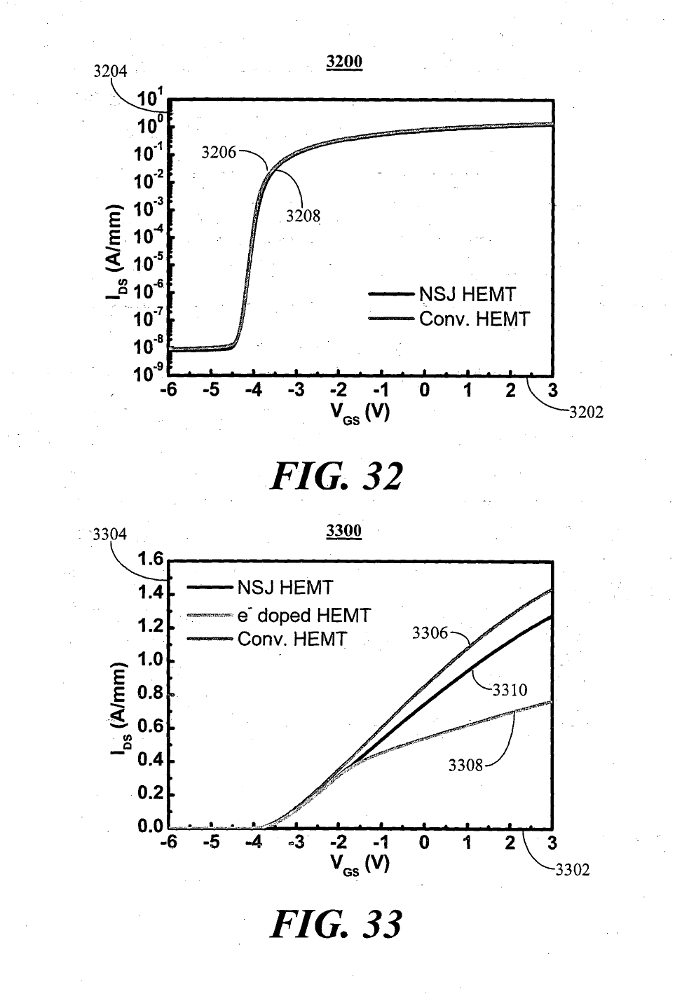

The simulated I-V characteristics of the NSJ III-nitride HEMT device 2810 and the conventional HEMT device 2902 are shown in FIGS. 31 to 33. FIG. 31 illustrates a graph 3100 in log scale of OFF state gate-source voltage 3102 versus drain-source current 3104 for the conventional HEMT device 2902 (on trace 3106) and for the NSJ III-nitride HEMT device 2810 (on trace 3108). FIG. 32 illustrates a graph 3200 in log scale at V_{DS}=20V of gate-source voltage 3204 versus drain-source current 3206 for the conventional HEMT device 2902 (on trace 3206) and the NSJ III nitride HEMT device 2810 (on trace 3208).

And FIG. 33 illustrates a graph 3300 in linear scale at V_{DS}=20V of gate-source voltage 3302 versus drain-source current 3304 for the conventional HEMT device 2902 (on trace 3306), a negative-doped HEMT device without a super junction (on trace 3308), and the NSJ HEMT device 2810 (on trace 3310). As can be seen from FIGS. 31 to 33, the NSJ HEMT device 2810 can achieve more than 200 V/μm (i.e., 1000V/5 μm) breakdown voltage, more than two times of breakdown voltage the conventional HEMT 2902. In addition, the ON state current density of the NSJ HEMT device 2810 is higher than 1.2 A/mm, advantageously evidencing good ON state current driving capability even with superior breakdown performance. The ON resistance of the NSJ HEMT device 2810 and the conventional HEMT device 2902 are 7.4 Ω·mm and 7.0 Ω·mm, respectively. The OFF state leakage of the NSJ HEMT device 2810 is slightly lower than the conventional HEMT device 2902 owing to the voltage screen effect of the lateral negative charge assisted super junction 2806.

In the graph 3300, the I-V characteristics of the negative charge doped III-nitride HEMT without an interval super junction structure is plotted on trace 3308. Without the alternating non-doped region, in the ON state the drain current will saturate very fast due to reduced 2 DEG density in the depleted region. Thus, even with the negative charge doping, the super junction 2806 is necessary to achieve good OFF state breakdown and ON state current driving simultaneously.

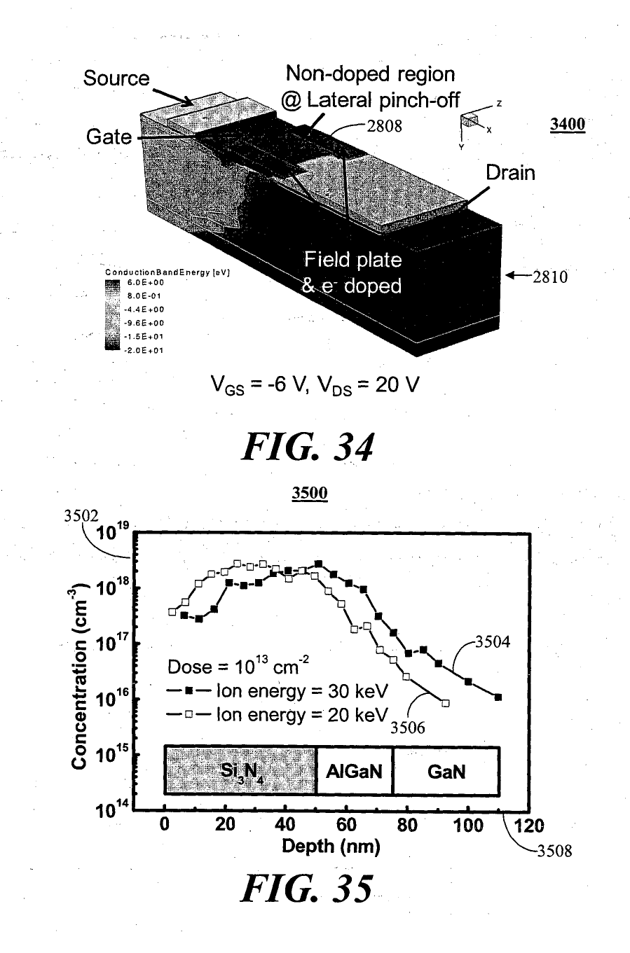

Referring to FIG. 34, a three-dimensional perspective view 3400 of the NSJ III-nitride HEMT device 2810 showing a conduction band distribution of the NSJ III-nitride HEMT device 2810 with a two finger gate field plate 2808 in the OFF state is illustrated. In the OFF state, the lateral pinch-off occurs between negative charge doped columns and non-doped columns. Therefore, even in the non-doped regions, the 2 DEG channel 2815 will be depleted, providing better uniformity of the electrical field and leading to superior breakdown performance.

During fabrication of the NSJ III-nitride HEMT device 2810, implantation of strong electron negativity ions (e.g. fluorine, oxygen) is needed to introduce negative charges into the ˜25 nm thick AlGaN barrier layer 2814. If the ions were directly implanted into the AlGaN barrier layer 2814, ultra low energy ion implantation (<1 keV) is needed. And due to the space charge effect, a beam current of low energy ion implantation is hard to maintain and a special doping process (e.g., cluster or plasma ion implantation) is usually used, raising the process cost and difficulties. In the NSJ III-nitride HEMT device 2810, ion implantation is performed after surface passivation. Therefore, the passivation layer advantageously provides an additional pre-deceleration and pre-scattering, leading to lower channeling effect and less dopant in the 2 DEG channel 2815. In order to analyze the ion implantation process, the process modeling was built using a molecular dynamics method. FIG. 35 illustrates a graph 3500 of F doping concentrations 3502 of ion implantation at 30 keV (plotted on trace 3504) and 20 keV (plotted on trace 3506) on a SiN/AlGaN/GaN epitaxial structure for the NSJ III-nitride HEMT device 2810 where the depth of ion implantation is plotted along the x-axis 3508. As can be seen in FIG. 35, with the pre-deceleration within the SiN passivation layer (e.g. 50 nm), standard ion implantation of F ions (30 keV) can be implemented in NSJ HEMT fabrication, making the process simpler and less costly.

The novel NSJ III-nitride HEMT device 2810 with includes surface passivation 2822, the gate dielectric layer 2820, the lateral negative charge assisted super junction (NSJ) 2806 and the interval-finger gate field plate 2808 has been described and simulations tested. The lateral super junction 2806 is formed by using interval ion implantation with strong electron negativity ions (e.g. fluorine, oxygen) in the drift region. After ion implantation, negative charges will be introduced into the AlGaN barrier layer 2814 along the drift region. Thus, electron carriers in the 2 DEG channel 2815 under the e− doped area can easily be fully depleted in the OFF state, thereby lowering the peak electrical field. On top of the negatively charged ion doping area, the interval-finger gate field plate 2808 is deposited to laterally pinch-off the NSJ 2806 and enhance the breakdown performance. The gate dielectric layer 2820 blocks the gate leakage current. Since less electrons will be injected into the high electrical field region within the super junction 2806, impact ionization can be suppressed thereby reducing the chance of avalanche breakdown and further improving the OFF state breakdown performance. Both normally-on and normally-off NSJ III-nitride transistors 2802 can be monolithically integrated on the same AlGaN/GaN hetero-structure 2804 epitaxial wafer.

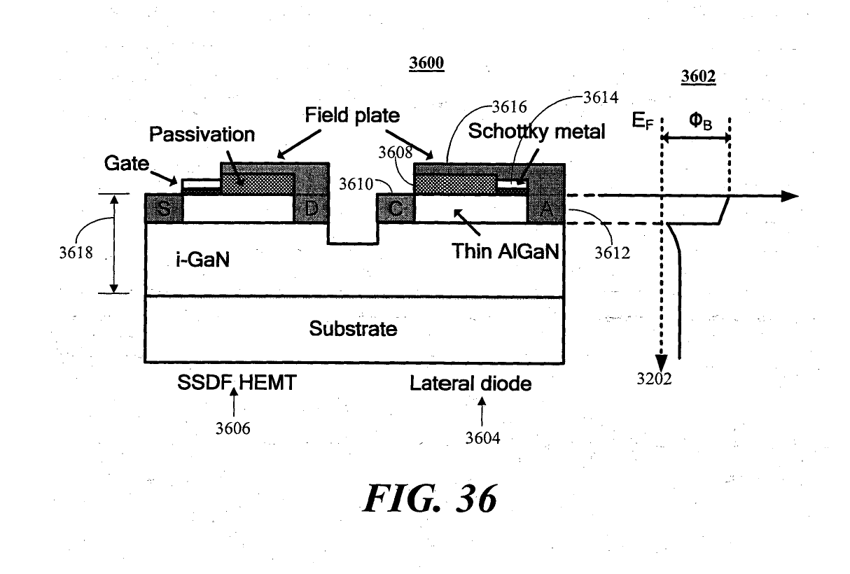

A fifth embodiment is shown in FIG. 36 which illustrates a schematic cross section view 3600 and a corresponding conduction band diagram 3602 of a native-off III-nitride power electronics platform including a normally-off SSDF HEMT 3606 and a lateral diode 3604. The III-nitride lateral diode 3604 combines surface passivation 3608, cathode and anode ohmic contacts 3610, 3612, a Schottky channel modulation plate 3614 and an anode field plate 3616. The III-nitride lateral diode 3604 is fabricated on a native-off AlGaN/GaN hetero junction structure 3618 and possesses unique characteristics to realize defect free, large current driving capability (38 kA/cm² at 20 V), low leakage (10⁻⁴ A/cm²), low turn on voltage (<0.5 V) and high stability.

Most importantly, the lateral diodes 3604 and normally-on/off SSDF HEMT devices 3606 can be monolithically integrated on the same native-off III-nitride AlGaN/GaN hetero junction structure 3618 wafer as shown in FIG. 36 using a singular fabrication process, thereby enabling a scalable complete power electronics platform with various types of devices. Based on the III-nitride power electronics platform depicted in FIG. 36 including the lateral diode 3604 and the normally-off SSDF HEMT 3606, high performance, low cost and high reliability compact power electronics circuits, such as switch based DC/DC converters, AC/AC converters, DC/AC inverters or AC/DC rectifiers can be fabricated.

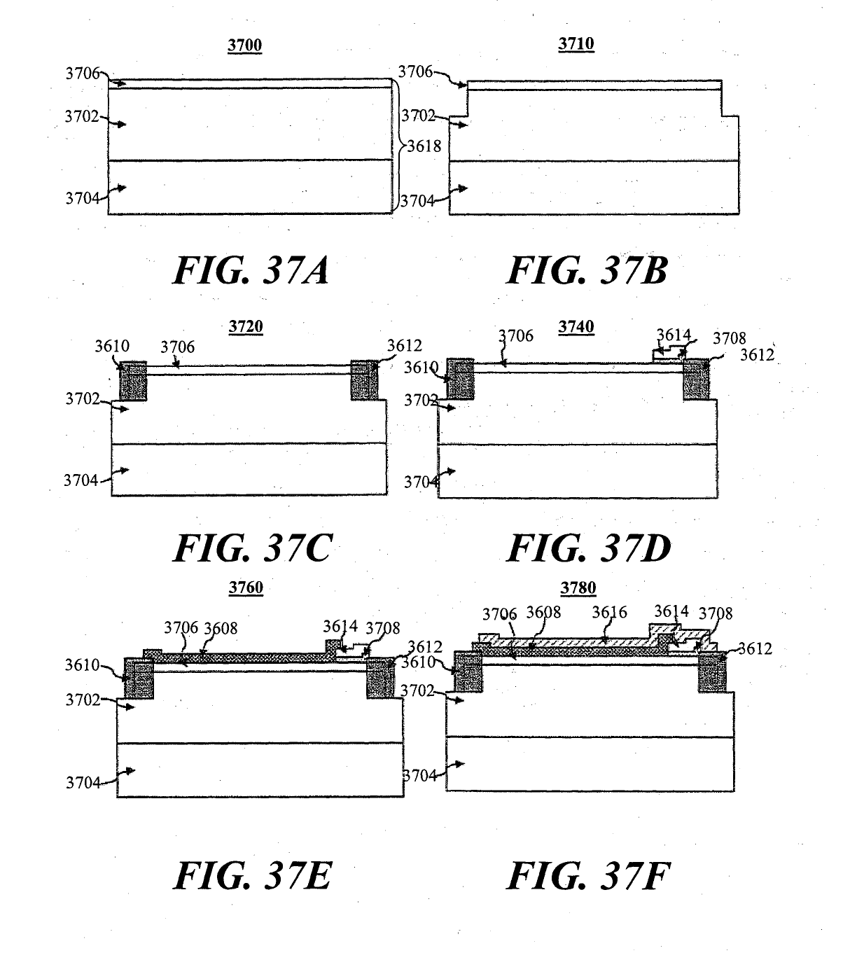

Referring to FIG. 37, including FIGS. 37A to 37F, the schematic cross section views 3700, 3710, 3720, 3740, 3760, 3780 depict the corresponding process flow of native-off III-nitride lateral diode 3604 in accordance with the fifth embodiment. Referring to FIG. 37A, the native-off AlGaN/GaN hetero-junction structure 3618 is fabricated by growing a GaN buffer layer 3702 on a substrate layer 3704 (e.g. Si, sapphire or SiC) by MOCVD and forming a thin (<10 nm) AlGaN barrier layer 3706 on the GaN buffer layer 3702. Within the native-off AlGaN/GaN hetero junction 3618, the conduction band of the AlGaN/GaN interface will be raised higher than Fermi level even without any external voltage bias. Thus, the electron carriers in the 2 DEG channel can be completely depleted. To turn on this device, a positive anode voltage is needed, thus diode operation behavior can be obtained. Therefore, the operation mechanism of the native-off lateral diode 3604 is based on the switching ON and OFF of a lateral 2 DEG channel by using a Schottky metal plate, which features a small turn on (build-in) voltage (<0.5 V compared to ˜1 V of SBD or p-i-n diode) and can further be tuned by applying a different thickness Schottky dielectric layer. As a result, the switching loss of the lateral diode in accordance with this fifth embodiment is low and the switching speed could be high, for example the switching speed could be comparable to the switching speed of a HEMT device.

Referring to FIG. 37B, the schematic cross section view 3710 depicts the process step of back etching an upper portion of the native-off AlGaN/GaN hetero-junction 3618 to form a mesa for device isolation. At step 3720 depicted in FIG. 37C, ohmic contacts for the cathode 3610 and the anode 3612 are formed. At step 3740 illustrated in FIG. 37D, the Schottky channel modulation metal plate 3614 is deposited on top of the thin AlGaN barrier 3706 and connected to the anode electrode 3612. At zero anode voltage bias, a 2 DEG channel under the Schottky metal plate can be fully pinched OFF, which results in low reverse leakage current; in forward state (at positive anode voltage bias), however, the electron carriers will accumulate at the hetero-interface thereby turning ON the 2 DEG channel to realize true diode behavior. In order to block the current through the Schottky interface to protect the Schottky interface, a Schottky dielectric layer 3708 is deposited between the Schottky channel modulation metal 3614 and the AlGaN barrier layer 3706 in the III-nitride diode 3604, allowing modulation of the diode turn on voltage from 0V to 0.5V.

Referring next to FIG. 37E, the surface passivation layer 3608 is formed over the AlGaN barrier layer 3706 at process step 3760. And, finally, at process step 3780 (FIG. 37F), the anode field plate 3616 is formed on top of the native-off III-nitride hetero-structure 3618. The surface passivation layer 3608 and the anode field plate 3616 enhance the on-state current driving capability of the III-nitride lateral diode 3604.

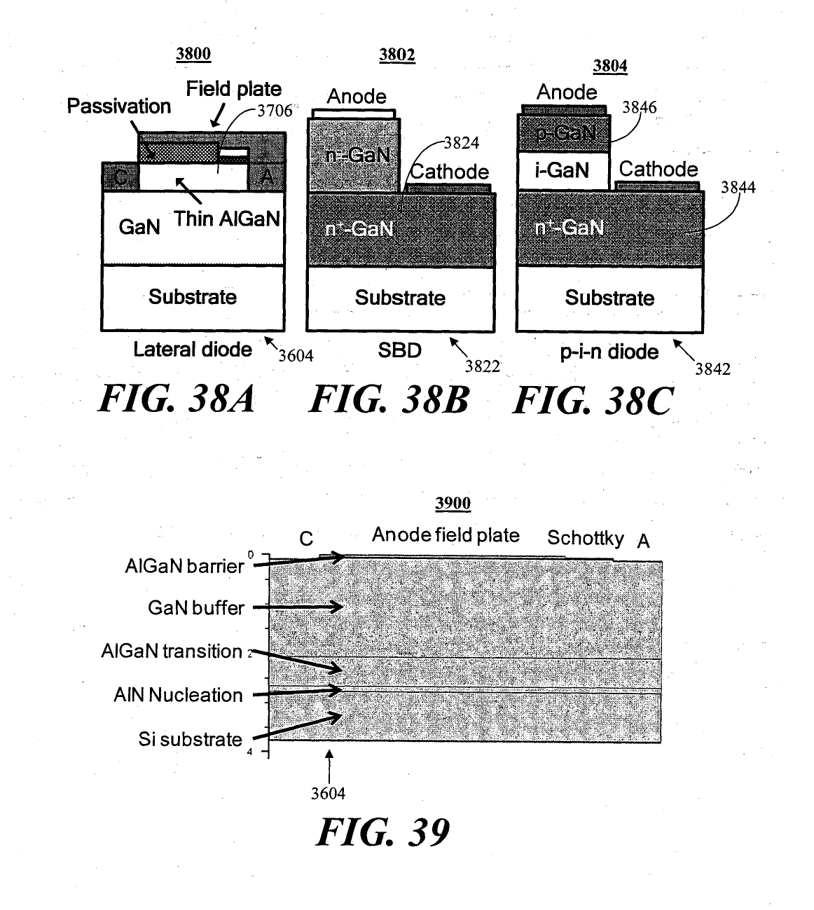

In order to characterize the device performance of the native-off III-nitride lateral diode 3604, device simulations of lateral diodes were done using the Senturaus tool. In addition to modeling of the III-nitride lateral diode 3604, the modeling of a GaN SBD and a p-i-n diode was also done for comparison. FIG. 38, comprising FIGS. 38A, 38B and 38C, illustrates schematic cross section views of these three diodes, wherein FIG. 38A is a schematic cross section view 3800 of the native-off III-nitride lateral diode 3604, FIG. 38B is a schematic cross section view 3820 of a GaN Schottky barrier diode (SBD) 3822, and FIG. 38C is a schematic cross section view 3840 of a GaN p-i-n diode 3842.

Each diode has the same device length of eight μm and uses the same physical models such as polarization and unintentional background doping (e.g., ˜10¹⁶ cm⁻³), AlGaN transition layer, and AlN nucleation layer, as shown in the epitaxial structure cross-section view 3900 of the native-off III-nitride lateral diode device 3604 model.

Particularly, in the native-off III-nitride lateral diode 3604, the AlGaN barrier thickness 3706 was set to five nm, which has an Al more fraction of 0.25. The contact lengths of the Schottky channel modulation metal plate 3616, the cathode ohmic contact 3610 and the anode ohmic contact 3612 were set to one μm. In the SBD 3822, the donor doping in the n⁺ region 3824 was set to 3×10¹⁸ cm⁻³, while in the p-i-n diode 3842, the doping level is set to 3×10¹⁸ and 1×10¹⁸ cm⁻³ for the n⁺3844 and the p region 3846, respectively.

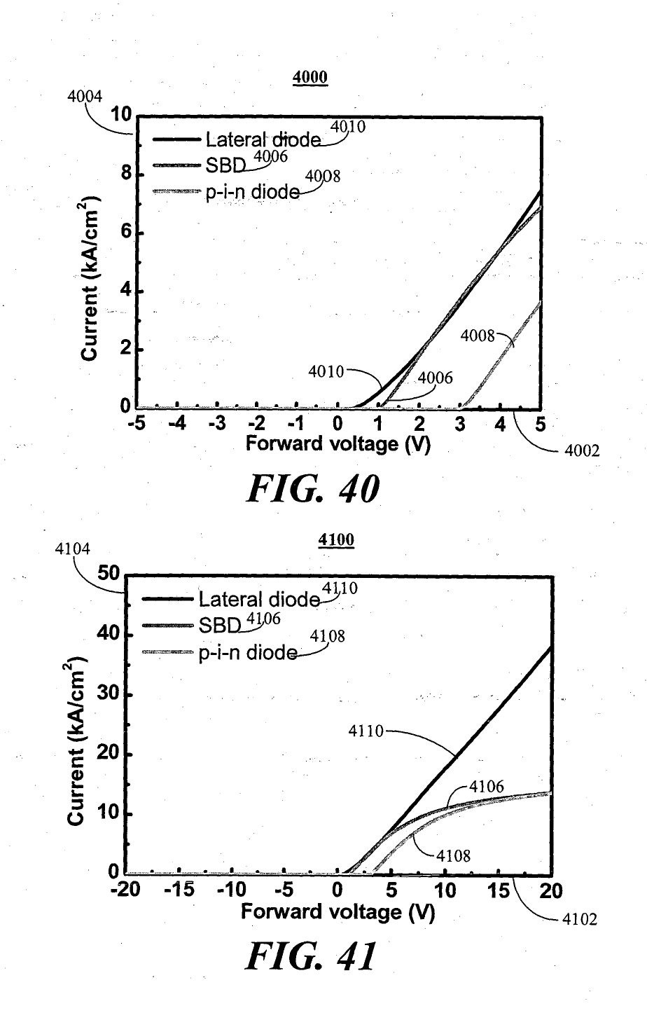

The I-V characteristics of the native-off III-nitride lateral diode 3604, the SBD 3822 and the p-i-n diode 3842 are shown in FIGS. 40 to 42. FIG. 40 illustrates a linear scale graph 4000 of current-voltage characteristics of the SBD device 3822, the p-i-n device 3842 and the native-off III-nitride lateral diode 3604 on traces 4006, 4008 and 4010, respectively, for voltages ranging from minus five volts to five volts, where the forward voltage is plotted along the x-axis 4002 and the current is plotted along the y-axis 4004.

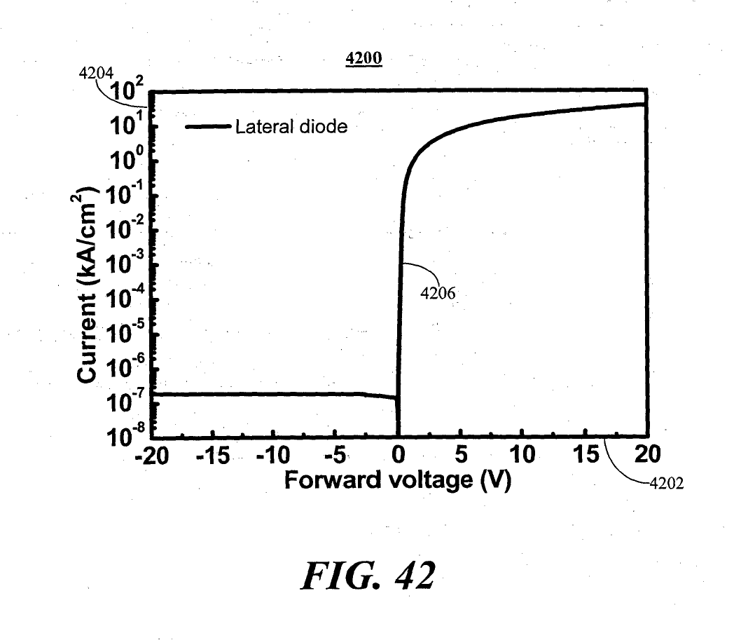

Referring to FIG. 41, a linear scale graph 4100 of current-voltage characteristics of the SBD device 3822, the p-i-n device 3842 and the native-off III-nitride lateral diode 3604 on traces 4106, 4108 and 4110, respectively, for voltages ranging from minus twenty volts to twenty volts, where the forward voltage is plotted along the x-axis 4102 and the current is plotted along the y-axis 4104. The graph 4200 in FIG. 42 shows the current-voltage characteristics of the native-off III-nitride lateral diode 3604 in log scale on a trace 4206 where the forward voltage is plotted along the x-axis 4202 and the current is plotted along the y-axis 4204.

By implementing the unique device structure of the native-off III-nitride lateral, diode 3604 in accordance with the fifth embodiment as a diode device similar to the SSDF HEMT device 703 (FIG. 7), the native-off III-nitride lateral diode 3604 can deliver a low OFF state leakage around 10⁻⁴ A/cm² (10 nA/mm) up to −20 V, indicating good turn-off behavior for high efficiency and low loss power applications. In the graph 4000, the Vₜᵤᵣₙ₋ₒₙ of the native-off III-nitride lateral diode 3604 with 5 nm AlGaN layer is 0.5V, comparing with SBD (1V) and p-i-n diode (3V). With the same device dimensions, the native-off III-nitride lateral diode 3604 can deliver much higher forward current driving density (38 kA/cm² at 20 V) than either the SBD 3822 or the p-i-n diode 3842 (e.g., about three times the forward current driving density of the SBD 3822 or the p-i-n diode 3842). In addition, due to the anode field plate 3616, the high forward current of the native-off III-nitride lateral diode 3604 will not be saturated at high anode voltage biases.

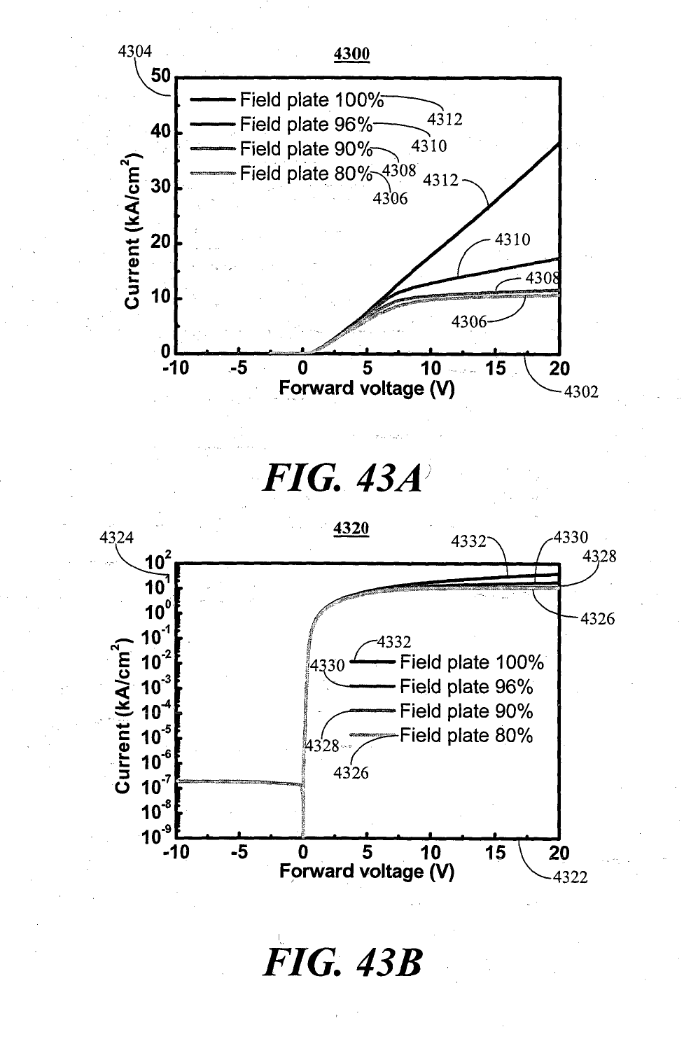

The anode field plate 3616 in the native-off HI-nitride lateral diode 3604 is used to enhance the current driving capability in forward and uniform electric field distributions along the 2 DEG channel. Referring to FIG. 43, including FIGS. 43A and 43B, the simulated current-voltage characteristics of the native-off III-nitride lateral diode 3604 with different anode field plate 3616 coverages are shown in linear scale (in graph 4300 of FIG. 43A and in log scale in graph 4320 of FIG. 43B. In the graph 4300, the forward voltage is plotted along the x-axis 4302 and the current in linear scale is plotted along the y-axis 4304. Traces 4306, 4308 4310 and 4312 depict the current-voltage characteristics when the anode field plate 3616 coverage is 80%, 90%, 96% and 100%, respectively. Similarly, in the graph 4320, the forward voltage is plotted along the x-axis 4322 and the current in log scale is plotted along the y-axis 4324. Traces 4326, 4328 4330 and 4332 depict the current-voltage characteristics when the anode field plate 3616 coverage is 80%, 90%, 96% and 100%, respectively,

As seen in the graphs 4300 and 4320, without full coverage of the anode field plate 3616, in forward voltage conditions, the conduction current will saturate at around 7V limiting device performance. Partially, (i.e., with 80% field plate 3616 coverage) the maximum ON current density (˜10 kA/cm²) will be only about one fourth of the maximum ON current density for the fully covered anode field plate 3616 (˜38 kA/cm² at 20 V). In addition, the increase of the ON current owing to the anode field plate 3616 coverage will not lead to an increase of the reverse leakage current of the native-off III-nitride lateral diode 3604, as shown in FIG. 43B, as opposed to the reverse leakage current effect from increasing the n-type doping concentration in the III-nitride SBD 3822 or the p-i-n diode 3842.

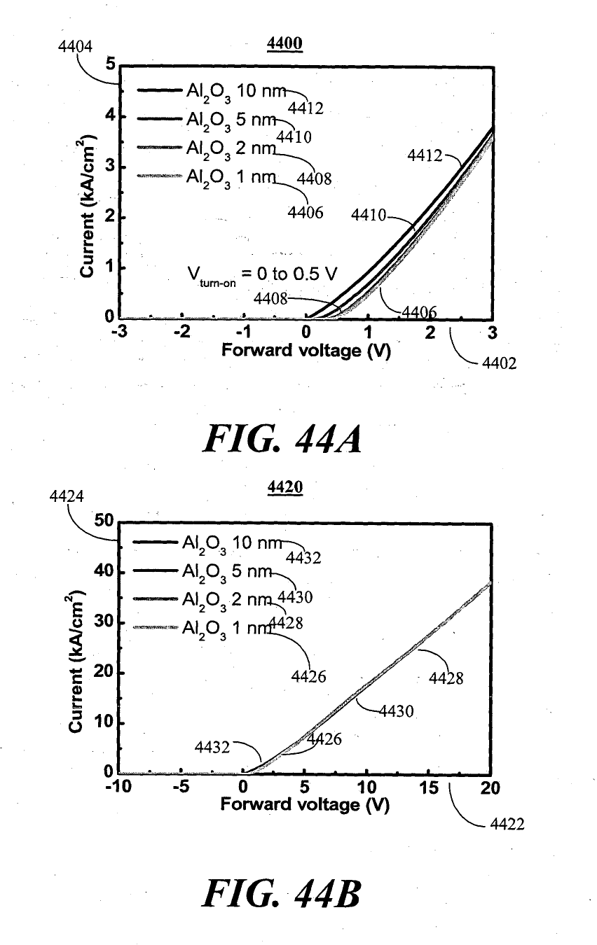

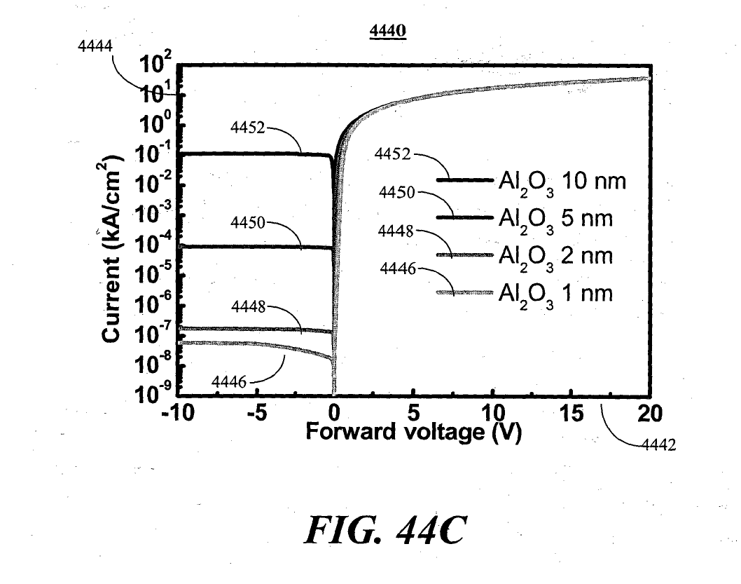

In the native-off III-nitride lateral diode 3604, the Schottky dielectric layer 3708 (e.g. Al₂O₃) is deposited between the Schottky channel modulation metal 3614 and the AlGaN barrier layer 3706 to block the current between the AlGaN barrier layer 3706 and the Schottky metal 3614, protect the Schottky metal interface, and modulate the device turn ON voltage. Referring to FIG. 44, including FIGS. 44A, 44B and 43C, graphs of current-voltage characteristics of the native-off III-nitride lateral diode 3604 having different Shottky dielectric 3708 thicknesses are depicted. FIG. 44A is a linear scale graph 4400 having voltages 4402 from minus three volts to three volts, FIG. 44B is a linear scale graph 4420 having voltages 4422 from minus ten volts to twenty volts, and FIG. 44C is a log scale graph 4440 having voltages 4442 from minus ten volts to twenty volts. Along the y-axes, the current 4404, 4424 is linearly plotted in graphs 4400 and 4420, and the current 4444 is plotted on a log scale in graph 4440.

The simulated current-voltage characteristics of the native-off III-nitride lateral diode 3604 for voltages from −3V to 3V are shown in the linear scale graph 4400 and traces 4406, 4408, 4410 and 4412 correspond to Shottky dielectric 3708 thicknesses of 1 nm, 2 nm, 5 nm and 10 nm. The simulated current-voltage characteristics of the native-off III-nitride lateral diode 3604 for voltages from −10V to 20V are shown in the graph 4420 and traces 4426, 4428, 4430 and 4432 correspond to Shottky dielectric 3708 thicknesses of 1 nm, 2 nm, 5 nm and 10 nm. Finally, the simulated current-voltage characteristics of the native-off III-nitride lateral diode 3604 for voltages from −10V to 20V are shown in the graph 4440 and traces 4446, 4448, 4450 and 4452 correspond to the Shottky dielectric 3708 thicknesses of 1 nm, 2 nm, 5 nm and 10 nm.

The simulation results in FIG. 44 illustrate that, similar to the native-off SSDF HEMT 3822, a thicker Al₂O₃ Schottky dielectric 3708 will provide a smaller Vₜᵤᵣₙ₋ₒₙ. Thus, the native-off III-nitride lateral diode 3604 can advantageously provide a turn-on voltage from 0 V to 0.5 V, providing greater flexibility for circuit design. In addition, the change of the lateral diodes' turn-on voltage will not result in any variation of the forward current density. However, it should be noted that a small Vₜᵤᵣₙ₋ₒₙ will result in high reverse leakage current as shown in FIG. 44C. This is due to the not fully pinched-off 2 DEG channel at zero anode voltage bias.

The novel native-off III-nitride lateral diode 3604 with the thin AlGaN barrier layer 3706, the cathode ohmic contact 3610 and the anode ohmic contact 3612, the surface passivation layer 3608, the Schottky channel modulation plate 3614 and the anode field plate 3616 provides a monolithically integratable device for a native-off III-nitride wafer, fabricatable in the same fabrication process with other native-off III-nitride GaN devices, realizing a low cost, highly scalable, high performance single-chip power electronics platform. Since the native-off III-nitride lateral diode 3604 is directly fabricated on the native-off AlGaN/GaN hetero-structure 3618 grown by MOCVD, no special process, such as gate recess, fluorine treatment or p-type doping is needed for normally-off transistor fabrication. Thus, a lot of advantages such as good uniformity, defect reduction, large current driving capability (e.g., 38 kA/cm² at 20V), low leakage (e.g., 10⁻⁴ A/cm²), low turn-on voltage (e.g., <0.5V) and high stability can be achieved, indicating good industry applicability for high speed, high efficiency and high temperature power electronics with low cost and compact size.

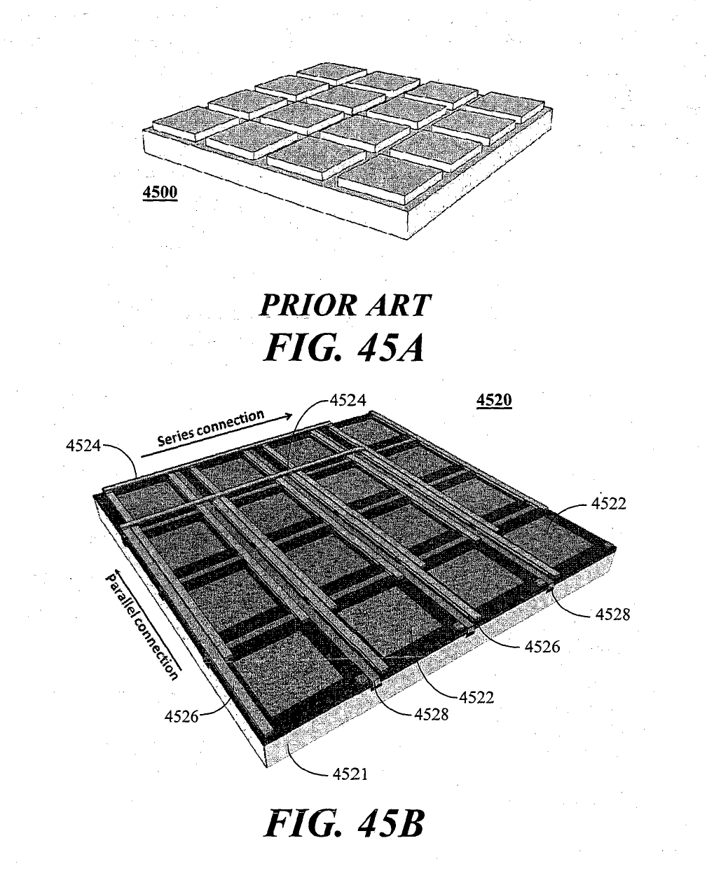

A conventional patterned silicon substrate 4500 AlGaN/GaN HEMT fabrication is depicted in FIG. 45A. Fluorine plasma ion implantation technology has been developed to fabricate normally-off AlGaN/GaN HEMTs using, for example, the conventional substrate in the perspective view 4500. By implanting negatively charged fluorine ions into the AlGaN barrier, free electrons in the 2 DEG channel can be depleted, thereby obtaining a positive threshold voltage. However, ultra low implantation energy (i.e., <1 keV) is needed for this technology and defects induced channel mobility and current degradation typically results.

In accordance with a sixth embodiment and based on the above-mentioned LCG technique, a novel concept for power systems is depicted in a perspective view 4530 of a substrate 4521 in FIG. 45B. On each mesa 4522, individual small AlGaN/GaN HEMT device structures are fabricated as single power units. These power units can be connected either in series (connectors 4524) or in parallel (connectors 4526) for current driving and/or voltage handling to form a highly flexible robust III-nitride power electronics platform on GaN-on-patterned Si substrates, such as the substrate 4520. A better thermal dissipation can be realized by insertion of dielectric materials with high thermal conductivity into trenches 4528 between the mesas 4522.

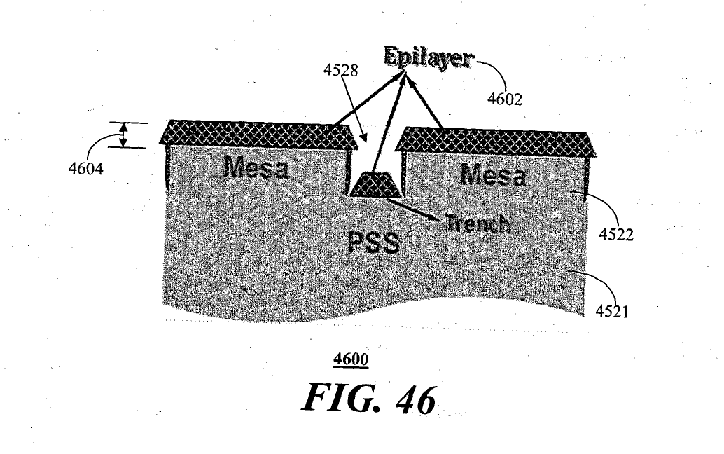

Referring to FIG. 46, a schematic cross-section view 4600 depicts that the Si (111) substrate 4520 is firstly patterned into mesa structures 4522 (100˜200)×(100˜200) μm² in size separated by 10-20 μm trenches 4528, which can effectively help to relax the tensile stress and lattice mismatch between a III-nitride epi-layer 4602 and the Si substrate 4520. AlGaN/GaN hetero-structures 4604 are then grown on this patterned Si substrate 4521 by lateral confined growth techniques using MOCVD. After the epitaxy process, the surface of the epi-structures will not be fully coalesced with clear gaps between neighboring mesas due to the difference in the growth rate of mesa and trench. By using this method, high quality III-nitride epi-layers can advantageously be achieved.

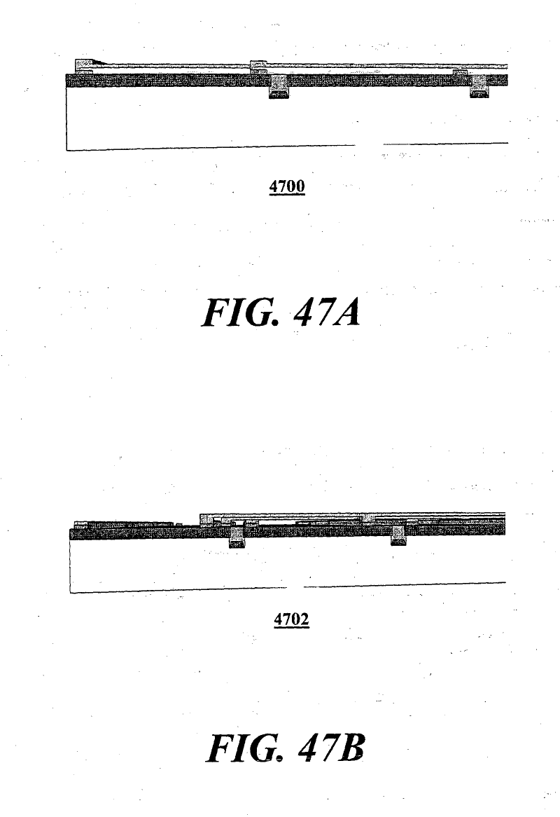

The AlGaN/GaN HEMT transistors are fabricated on top of the mesas 4522 and exhibit high quality with low dislocation densities together with a thick buffer layer. Thus, both high ON state current driving capability and OFF state breakdown voltage of fabricated HEMTs can be achieved simultaneously. Referring to FIG. 47, including FIGS. 47A and 47B, schematic cross-section views 4700, 4702 after fabrication are illustrated, where the schematic cross section view 4700 depicts parallel connections and the schematic cross section view 4702 depicts series connections.

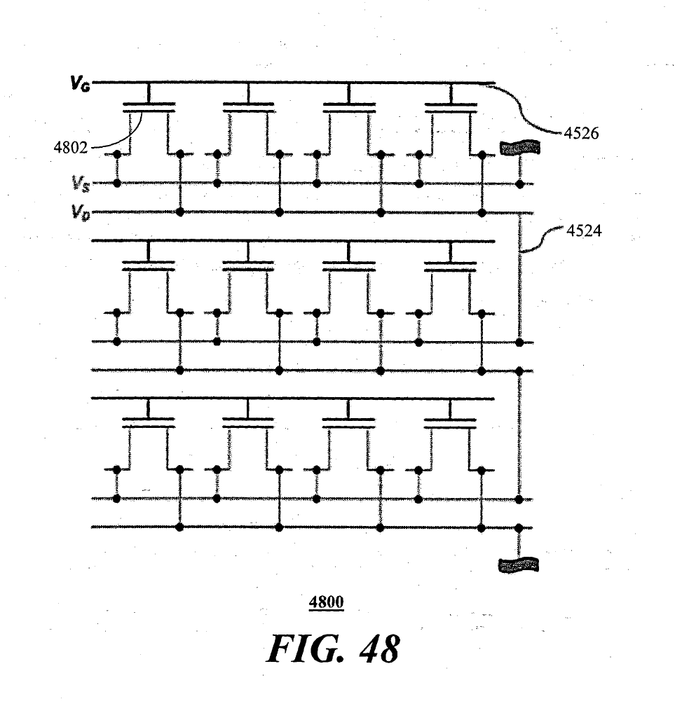

In the integrated power system, each transistor behaves as a single power unit. Particularly, transistors in parallel can deliver multiplied output current while transistors in series can share the drain voltage, thereby significantly enhancing the breakdown performance. Based on this matrix configuration, truly flexible power delivering capability with various output currents and voltage levels can be achieved to meet the requirements of different power electronics systems. FIG. 48 illustrates a circuit diagram 4800 of the electrical scheme of the power integration system where the transistors 4802 can be connected in parallel by the horizontal connectors 4526 or connected in series by the vertical connectors 4524.

In addition, in the trench area, dielectric material with high thermal conductivity such as BeO can be inserted to provide improved electrical isolation between individual transistors while enhancing heat dissipation within the power system. As a′ result, monolithic integrated effective cooling can be realized in the III-nitride integrated power system depicted in FIGS. 45 to 48. Further, the III-nitride integrated power system provides flexible power delivering and handling capability based on the high quality MOCVD grown AlGaN/GaN hetero-structures on Patterned Si (111) substrates 4521.

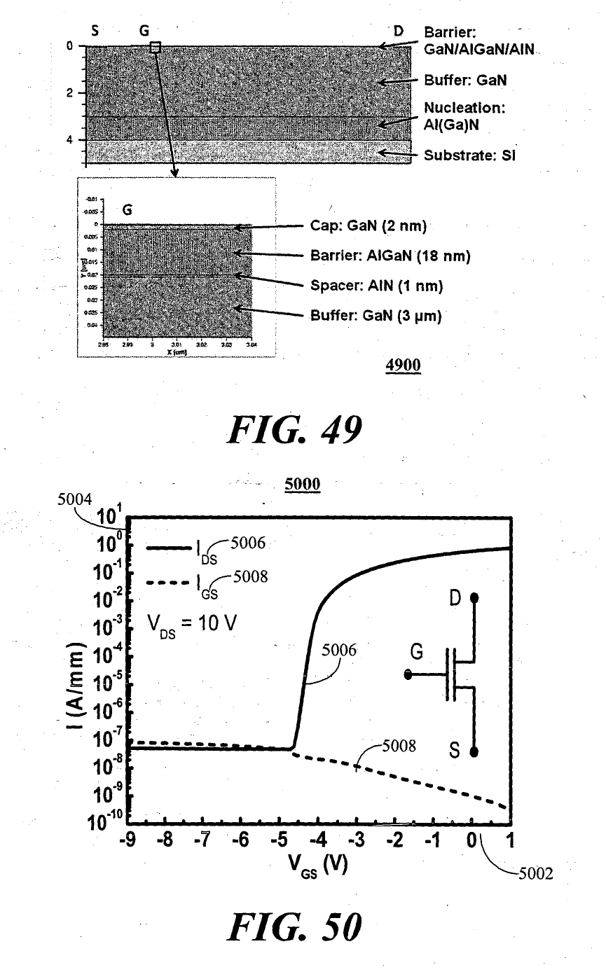

In order to characterize the device performance of the III-nitride integrated power system, simulations have been done using the Senturaus tool. The modeling of a single transistor and transistors in parallel and in series has been modeled. Each transistor has the same device configuration and the same physical models (e.g., polarization, unintentional background doping (˜10¹⁶ cm⁻³) and AlN nucleation layer) as shown in FIG. 49. FIG. 49 illustrates a schematic cross section view 4900 of an epitaxial structure of a single AlGaN/GaN HEMT transistor used in modeling the power integration system in accordance with the sixth embodiment. The gate width (W_{G}) is set to 200 μm, and based upon this parameter, the outputs Iₘₐₓ and V_{D} gives 0.166 A and 10V, respectively. FIG. 50 illustrates a log scale graph 5000 of gate-source voltage 5002 versus drain-source current 5004 transfer characteristics of a single transistor in the power integration system in accordance with the sixth embodiment where Iₘₐₓ of the drain-source current (plotted on trace 5006) is 0.166 A and V_{D}=10V. The gate-source current is plotted on trace 5008.

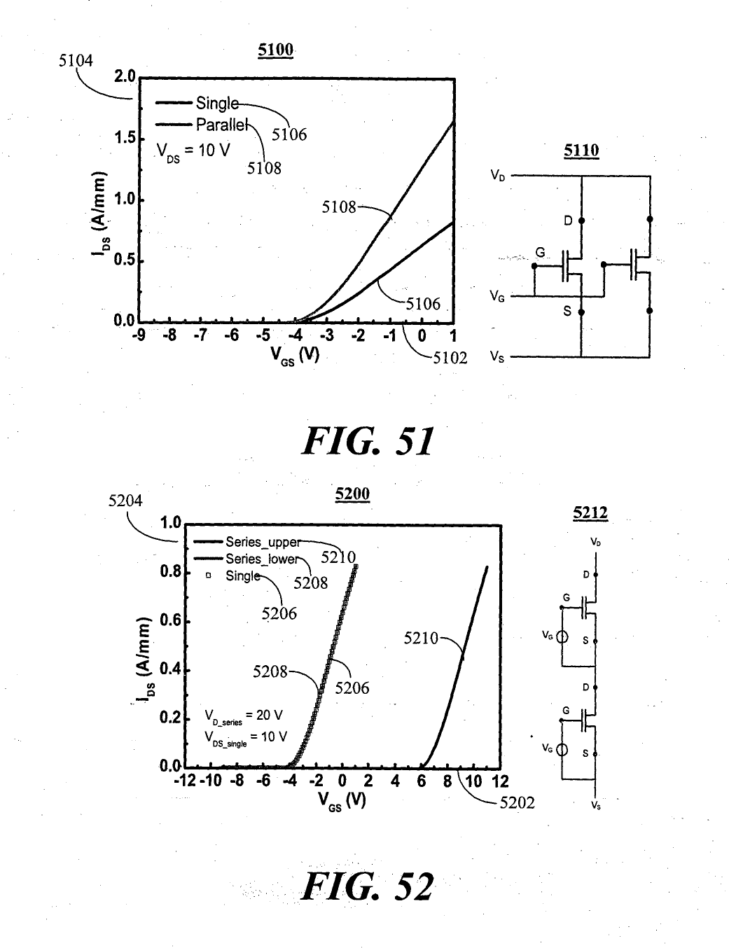

For the simulations of transistors in parallel and in series, respectively, we chose two transistors for an example. The simulated results of transfer characteristics for parallel and series configuration are shown in FIGS. 51 and 52, respectively. FIG. 51 illustrates a linear scale graph 5100 of gate-source voltage 5102 versus drain-source current 5104 transfer characteristics of a single transistor 5106 and a double transistor pair 5108 connected in parallel (shown in circuit diagram 5110) where Iₘₐₓ=0.332 A and V_{D}=10V.

FIG. 52 illustrates a linear scale graph 5200 of gate-source voltage 5202 versus drain-source current 5204 transfer characteristics of a single transistor 5206 and each transistor 5208, 5210 in a double transistor pair connected in series (shown in circuit diagram 5212) where Iₘₐₓ=0.166 A and V_{D}=20V. From FIGS. 51 and 52, those skilled in the art will realize that when the two transistors are connected in parallel, the current driving is doubled with Iₘₐₓ reaching 0.332 A, while the voltage handling is doubled to 20V for V_{D} when the two transistors are aligned in series.

Thus, it can be seen that a novel power integration system with a flexible power output based on high quality AlGaN/GaN HEMTs grown on patterned Si (111) substrates has been provided. The power integration system effectively takes advantage of lateral confined growth technique with a continuous crack-free thick buffer layer (˜2-3 μm, no interlayer needed) together with a low dislocation density. Flexible power output is realized by matrix configuration of the power units where units in a row are connected in parallel while series connections for units in a column are adopted. Therefore, by controlling the number of rows and units in a row, respectively, the output current and voltage can be flexibly manipulated. Monolithic integrated effective cooling can also be realized by inserting dielectric materials with high thermal conductivity into the trenches.

Thus, it can be seen that the present embodiments provide highly scalable, reliable GaN structures and fabrication techniques for HEMT devices and diode devices having small size and robust operational parameters. In addition, the present embodiments provide normally-off III-nitride GaN structures for diode and transistor applications exhibiting novel and useful current-voltage characteristics as well as higher yield and smaller cost. While exemplary embodiments have been presented in the foregoing detailed description of the invention, it should be appreciated that a vast number of variations exist.

It should further be appreciated that the exemplary embodiments are only examples, and are not intended to limit the scope, applicability, operation, or configuration of the invention in any way. Rather, the foregoing detailed description will provide those skilled in the art with a convenient road map for implementing an exemplary embodiment of the invention, it being understood that various changes may be made in the function and arrangement of elements and method of operation described in an exemplary embodiment without departing from the scope of the invention as set forth in the appended claims.

1. (canceled)

2. A GaN high electron mobility transistor comprising:
a substrate;
a AlGaN/GaN heterostructure grown on the substrate, the AlGaN/GaN heterostructure comprising a GaN buffer layer and a AlGaN barrier layer; and
a normally-off GaN III-nitride device fabricated from the AlGaN/GaN heterostructure, wherein the normally-off GaN III-nitride device is a device selected from the group comprising a normally-off vertical GaN III-nitride HEMT device, a self-aligned source ohmic contact and drain field plate (SSDF) III-nitride HEMT device, a surface state energy level modulated (SSEM) III-nitride HEMT device, and a lateral negative charge assisted super junction (NSJ) III-nitride HEMT device.

3. The GaN HEMT structure in accordance with claim 2 wherein the normally-off GaN III-nitride device is a lateral NSJ III-nitride HEMT device, and wherein the lateral NSJ III-nitride HEMT device comprises a lateral negative charge assisted super junction.

4. The GaN HEMT structure in accordance with claim 2 wherein the normally-off GaN III-nitride device is a lateral NSJ III-nitride HEMT device, and wherein the lateral NSJ III-nitride HEMT device comprises an interval-finger gate field plate.

5. The GaN HEMT structure in accordance with claim 2 wherein the normally-off GaN III-nitride device is a lateral NSJ III-nitride HEMT device, and wherein the lateral NSJ III-nitride HEMT device comprises a surface passivation layer and/or a gate dielectric layer.

6. (canceled)

7. The GaN HEMT structure in accordance with claim 2 wherein the normally-off GaN III-nitride device is a SSEM III-nitride HEMT device, and wherein the SSEM III-nitride HEMT device comprises a SSEM layer to suppress surface trapping/detrapping and current collapse.

8. The GaN HEMT structure in accordance with claim 2 wherein the normally-off GaN III-nitride device is a SSEM III-nitride HEMT device, and wherein the SSEM III-nitride HEMT device comprises a negative charge doped gate dielectric layer to block gate leakage current and prevent current collapse.

9. The GaN HEMT structure in accordance with claim 2 wherein the normally-off GaN III-nitride device is a SSEM III-nitride HEMT device, and wherein the SSEM III-nitride HEMT device comprises a source field plate to enhance breakdown performance and stability of the SSEM III-nitride HEMT device.

10. The GaN HEMT structure in accordance with claim 2 wherein the normally-off GaN III-nitride device is a SSDF III-nitride HEMT device, and wherein the SSDF III-nitride HEMT device comprises a thin AlGaN barrier layer.

11. The GaN HEMT structure in accordance with claim 2 wherein the normally-off GaN III-nitride device is a SSDF III-nitride HEMT device, and wherein the SSDF III-nitride HEMT device comprises a surface passivation layer and/or a self-aligned source ohmic contact and/or a drain field plate.

12. (canceled)

13. (canceled)

14. The GaN HEMT structure in accordance with claim 2 wherein the normally-off GaN III-nitride device is a normally-off vertical GaN HEMT device, and wherein the normally-off vertical GaN HEMT device comprises a GaN regrowth layer.

15. The GaN HEMT structure in accordance with claim 2 wherein the normally-off GaN III-nitride device is a normally-off vertical GaN HEMT device, and wherein the normally-off vertical GaN HEMT device comprises a SiN layer.

16. A native-off III-nitride lateral diode structure comprising:
a substrate;
a AlGaN/GaN heterostructure grown on the substrate, the AlGaN/GaN heterostructure comprising a GaN buffer layer and a AlGaN barrier layer; and
a normally-off GaN III-nitride device fabricated from the AlGaN/GaN heterostructure, wherein the normally-off GaN III-nitride device includes a surface passivation layer.

17. The lateral diode structure in accordance with claim 16 further comprising a cathode ohmic contact and/or an anode ohmic contact.

18. (canceled)

19. (canceled)

20. The lateral diode structure in accordance with claim 16 further comprising a Schottky channel modulation plate and/or an anode field plate.

21. (canceled)

22. An integrated chip-level power system comprising:
a substrate;
a AlGaN/GaN heterostructure layer grown on the substrate, the AlGaN/GaN heterostructure layer comprising a GaN buffer layer and a AlGaN barrier layer, the AlGaN/GaN heterostructure layer formed into mesa areas and valley areas; and
a plurality of normally-off GaN III-nitride devices, each of the plurality of normally-off GaN III-nitride devices fabricated from a separate one of the mesa areas.

23. The integrated chip-level power system in accordance with claim 22 further comprising a first set of connectors for connecting two or more of the plurality of normally-off GaN III-nitride devices in series.

24. The integrated chip-level power system in accordance with claim 22 further comprising a second set of connectors for connecting two or more of the plurality of normally-off GaN III-nitride devices in parallel.

25. The integrated chip-level power system in accordance with claim 22 further comprising dielectric material with a high thermal conductivity located in the trench areas for monolithic integrated cooling and thermal management of the integrated chip-level power system.

26. The integrated chip-level power system in accordance with claim 22 wherein one or more of the plurality of normally-off GaN III-nitride devices comprises a normally-off GaN III-nitride HEMT device selected from the group comprising a normally-off vertical GaN III-nitride HEMT device, a self-aligned source ohmic contact and drain field plate (SSDF) III-nitride HEMT device, a surface state energy level modulated (SSEM) III-nitride HEMT device, and a lateral negative charge assisted super junction (NSJ) III-nitride HEMT device.

27. The integrated chip-level power system in accordance with claim 22 wherein one or more of the plurality of normally-off GaN III-nitride devices comprises a native-off III-nitride lateral diode.

28-51. (canceled)
